(19) United States
(12) Patent Application Publication
(10) Pub. No.: US 2026/0347697 A1
(43) Pub. Date: Nov. 5, 2026

(54) PREPARATION METHOD FOR PATTERNED QUANTUM DOT THIN FILM, AND PHOTOELECTRIC DEVICE AND ELECTRONIC DEVICE

(71) Applicants: Tsinghua University, Beijing (CN); TCL Technology Group Corporation, Huizhou, Guangdong (CN)

(72) Inventors: Hao ZHANG, Beijing (CN); Zhong FU, Beijing (CN); Likuan ZHOU, Beijing (CN)

(73) Assignees: Tsinghua University, Beijing (CN); TCL Technology Group Corporation, Huizhou, Guangdong (CN)

(21) Appl. No.: 19/115,236

(22) PCT Filed: Sep. 22, 2023
(86) PCT No.: PCT/CN2023/120673

§ 371 Date: Mar. 25, 2025

(30) Foreign Application Priority Data
Sep. 26, 2022 (CN) 202211175684.X

(51) Int. Cl. C09K 11/88; C09K 113/00; H10K 50/115; H10K 50/15; H10K 50/16; H10K 50/17; H10K 71/12; H10K 71/20; H10K 85/10; H10K 102/10

(52) U.S. Cl. CPC C09K 11/883; H10K 50/115; H10K 50/15; H10K 50/16; H10K 50/17; H10K 71/12; H10K 71/20; H10K 85/1135; C09K 2113/00; H10K 2102/103

(57) ABSTRACT

Disclosed are a preparation method for a patterned quantum dot thin film, a photoelectric device and an electronic device. The preparation method includes steps of forming a quantum dot film layer on one side of a substrate, wherein the quantum dot film layer includes a ligand remover and a quantum dot with ligands connected to the surface of the quantum dot, then performing partial exposure processing on the quantum dot film layer to enable the quantum dot film layer to include an exposed part and an unexposed part, and then removing the unexposed part to obtain a pattered quantum dot thin film.

The present application claims priority to Chinese Patent Application No. 202211175684.X, filed on Sep. 26, 2023, and entitled “PREPARATION METHOD FOR PATTERNED QUANTUM DOT THIN FILM, AND PHOTOELECTRIC DEVICE AND ELECTRONIC DEVICE”, the entire contents of all of which are incorporated herein by reference.

### TECHNICAL FIELD

The present disclosure relates to a technical field of photoelectric technology, and in particular to a preparation method for a patterned quantum dot thin film, a photoelectric device and an electronic device.

### BACKGROUND

A quantum dot, also known as a semiconductor nanocrystal, is a nanocrystal with a radius less than or close to the exciton Bohr radius, and a particle size is usually between 1 nm and 20 nm. The quantum dot has a unique fluorescence nano-effect, and a luminescence wavelength of the quantum dot may be regulated by changing its size and composition. The quantum dot has advantages of a narrow luminescence spectrum at half maximum width, high color purity, good light stability, a wide excitation spectrum and a controllable emission spectrum, and thus has broad application prospects in fields such as photovoltaic power generation technology, photoelectric display technology, and biological probe technology.

In the field of photoelectric display technology, the quantum dot may be used as a light-emitting material, and the quantum dot is usually used as a light-emitting layer in a form of a thin film, such as a patterned quantum dot thin film. A conventional patterning method of a quantum dot thin film has some defects that compared with the quantum dot thin film before patterning, a photoluminescence quantum yield of the quantum dot thin film after patterning may decrease significantly, thus negatively affecting a luminescence performance of the quantum dot thin film.

### Technical Solutions

Accordingly, the present disclosure provides a patterned quantum dot thin film, a photoelectric device and an electronic device to improve a problem that a quantum dot thin film after patterning has a significant decrease in photoluminescence quantum yield.

In a first aspect, the present disclosure provides a preparation method for a patterned quantum dot thin film including:
forming a quantum dot film layer including a quantum dot and a ligand remover on one side of a substrate provided, wherein a surface of the quantum dot is connected with a ligand;
performing a partial exposure process on the quantum dot film layer such that the quantum dot film layer includes an exposed part and an unexposed part, wherein the ligand in the exposed part is detached from the quantum dot; and
removing the unexposed part to obtain the patterned quantum dot thin film;
wherein the ligand remover is a compound represented by the following general formula (I):

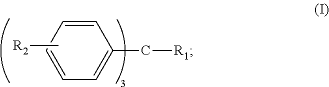

in the general formula (I), R₂ is selected from at least one of a hydrogen atom, a halogen atom, a substituted or unsubstituted alkyl group, a substituted or unsubstituted alkoxy group, a substituted or unsubstituted aryl group, and a substituted or unsubstituted heteroaryl group; and
in the partial exposure process, the ligand remover in the exposure part loses R₁ to form an electrophilic group, so that the ligand in the exposure part binds to the electrophilic group and is detached from the quantum dot.

In a second aspect, the present disclosure provides a photoelectric device including:
an anode;
a cathode disposed opposite the anode; and
a light-emitting layer disposed between the anode and the cathode;
wherein the light-emitting layer includes a plurality of quantum dot layers, a material of each of the quantum dot layers includes a quantum dot with at least one emission color, and a preparation method for at least one quantum dot layer of the quantum dot layers includes the following steps:
forming a quantum dot film layer including a quantum dot and a ligand remover on one side of a substrate provided, wherein a surface of the quantum dot is connected with a ligand;
performing a partial exposure process on the quantum dot film layer such that the quantum dot film layer includes an exposed part and an unexposed part, wherein the ligand in the exposed part is detached from the quantum dot; and
removing the unexposed part to obtain the patterned quantum dot thin film;
wherein the ligand remover is a compound represented by the following general formula (I):

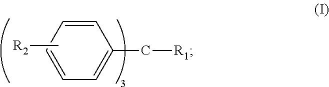

in the general formula (I), R₂ is selected from at least one of a hydrogen atom, a halogen atom, a substituted or unsubstituted alkyl group, a substituted or unsubstituted alkoxy group, a substituted or unsubstituted aryl group, and a substituted or unsubstituted heteroaryl group; and
in the partial exposure process, the ligand remover in the exposure part loses R₁ to form an electrophilic group, so that the ligand in the exposure part binds to the electrophilic group and is detached from the quantum dot.

In a third aspect, the present disclosure provides an electronic device including a photoelectric device, wherein the photoelectric device includes:
an anode;
a cathode disposed opposite the anode; and
a light-emitting layer disposed between the anode and the cathode;
wherein the light-emitting layer includes a plurality of quantum dot layers, a material of each of the quantum dot layers includes a quantum dot with at least one emission color, and a preparation method for at least one quantum dot layer of the quantum dot layers includes the following steps:
forming a quantum dot film layer including a quantum dot and a ligand remover on one side of a substrate provided, wherein a surface of the quantum dot is connected with a ligand;
performing a partial exposure process on the quantum dot film layer such that the quantum dot film layer includes an exposed part and an unexposed part, wherein the ligand in the exposed part is detached from the quantum dot; and
removing the unexposed part to obtain the patterned quantum dot thin film;
wherein the ligand remover is a compound represented by the following general formula (I):

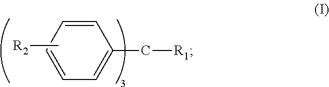

in the general formula (I), R₂ is selected from at least one of a hydrogen atom, a halogen atom, a substituted or unsubstituted alkyl group, a substituted or unsubstituted alkoxy group, a substituted or unsubstituted aryl group, and a substituted or unsubstituted heteroaryl group; and
in the partial exposure process, the ligand remover in the exposure part loses R₁ to form an electrophilic group, so that the ligand in the exposure part binds to the electrophilic group and is detached from the quantum dot.

### Advantageous Effects

A preparation method for a patterned quantum dot thin film in the present disclosure may prepare quantum dots with different structural compositions to form a patterned thin film, and a pattern resolution may reach 4 microns. The preparation method has advantages of high pattern resolution, high universality, a simple preparation process, and suitability for large-scale industrial production. A whole patterning process does not involve a process of damaging a quantum dot such as ligand exchange, so that a photoelectric property of the quantum dot before and after patterning may not be significantly changed. For example, a photoluminescence quantum yield of a red quantum dot remains the same before and after patterning, a photoluminescence quantum yield of a green quantum dot after patterning is 90% of that before patterning, and for a blue quantum dot with poor stability and sensitive surfaces, a photoluminescence quantum yield of the blue quantum dot after patterning is 70% of that before patterning.

### BRIEF DESCRIPTION OF THE DRAWINGS

In order to illustrate technical solutions in the embodiments of the present disclosure more clearly, accompanying drawings involved in a description of the embodiments may be briefly described below. It may be apparent that the accompanying drawings in the following description are merely some of the embodiments of the present disclosure, and other drawings may be obtained according to these drawings for those skilled in the art without involving any inventive effort.

FIG. 1 is a flow chart schematic diagram of a first preparation method for a patterned quantum dot thin film according to an embodiment of the present disclosure.

FIG. 2 is a mechanism schematic diagram of patterning a quantum dot thin film according to an embodiment of the present disclosure.

FIG. 3 is a flow chart schematic diagram of a second preparation method for a patterned quantum dot thin film according to another embodiment of the present disclosure.

FIG. 4 is a schematic structural diagram of a first photoelectric device according to an embodiment of the present disclosure.

FIG. 5 is an optical photograph of a patterned quantum dot thin film according to Example 1 of the present disclosure under a fluorescence microscope.

FIG. 6 is an optical photograph of a patterned quantum dot thin film according to Example 2 of the present disclosure under a fluorescence microscope.

FIG. 7 is an optical photograph of a patterned quantum dot thin film according to Example 3 of the present disclosure under a fluorescence microscope.

FIG. 8 is an optical photograph of a patterned quantum dot thin film according to Example 4 of the present disclosure under a fluorescence microscope.

FIG. 9 is a graph showing changes in photoluminescence quantum yields of a red quantum dot, a green quantum dot, and a blue quantum dot before and after patterning according to Example 4 of the present disclosure.

FIG. 10 is an optical photograph of a patterned quantum dot thin film according to Example 5 of the present disclosure under a bright field optical microscope.

FIG. 11 is an optical photograph of a patterned quantum dot thin film according to Example 6 of the present disclosure under a fluorescence microscope.

FIG. 12 is an optical photograph of a patterned quantum dot thin film according to Example 7 of the present disclosure under a fluorescence microscope.

FIG. 13 is a schematic structural diagram of a second photoelectric device according to an embodiment of the present disclosure.

FIG. 14 is an optical photograph of a light-emitting layer of a photoelectric device according to Example 8 of the present disclosure under a fluorescence microscope, and the light-emitting layer has a quantum dot array structure.

FIG. 15 is an optical photograph of a quantum dot thin film according to Comparative Example 1 of the present disclosure under a fluorescence microscope.

FIG. 16 is a characteristic curve graph of photoelectric devices according to Example 11 and Comparative Example 2 of the present disclosure, wherein A is a current density-electroluminescence intensity-voltage characteristic curve graph of photoelectric devices according to Example 11 and Comparative Example 2, B is an external quantum efficiency-electroluminescence intensity characteristic curve graph of photoelectric devices according to Example 11 and Comparative Example 2, and C is a photoluminescence quantum yield-time characteristic curve graph of photoelectric devices according to Example 11 and Comparative Example 2.

FIG. 17 is a characteristic curve graph of photoelectric devices according to Example 12 and Comparative Example 3 of the present disclosure, wherein D is a current density-electroluminescence intensity-voltage characteristic curve graph of photoelectric devices according to Example 12 and Comparative Example 3, E is an external quantum efficiency-electroluminescence intensity characteristic curve graph of photoelectric devices according to Example 12 and Comparative Example 3, and F is a photoluminescence quantum yield-time characteristic curve graph of photoelectric devices according to Example 12 and Comparative Example 3.

FIG. 18 is a characteristic curve graph of photoelectric devices according to Example 13 and Comparative Example 4 of the present disclosure, wherein G is a current density-electroluminescence intensity-voltage characteristic curve graph of photoelectric devices according to Example 13 and Comparative Example 4, H is an external quantum efficiency-electroluminescence intensity characteristic curve graph of photoelectric devices according to Example 13 and Comparative Example 4, and I is a photoluminescence quantum yield-time characteristic curve graph of photoelectric devices according to Example 13 and Comparative Example 4.

### DETAILED DESCRIPTION OF EMBODIMENTS

Embodiments of the present disclosure may be described clearly and fully below in connection with accompanying drawings in the embodiments of the present disclosure. It may be apparent that the embodiments described are merely a part of embodiments of the present disclosure, rather than all the embodiments. Based on the embodiments in the present disclosure, all other embodiments obtained by a person skilled in the art without involving any inventive effort are within the scope of the present disclosure.

An order of description of the following embodiments is not intended to limit a preferred order of the embodiments. Terms such as “first”, “second”, “third”, etc. are merely used as labels and do not impose numerical requirements or establish an order. Each embodiment of the present disclosure may be presented in a form of range. It should be understood that a description in the form of range is merely for convenience and brevity, and should not be construed as a limitation on a scope of the disclosure. Accordingly, it should be considered that a recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, 6, and the like, which is applicable for any range. Additionally, whenever a range of values is indicated herein, it is meant to include any recited number (fractional or integer) within the indicated range.

In the present disclosure, “including/includes” means “including but being not limited to/includes but is not limited to”.

In the present disclosure, “and/or” is configured to describe an association of associated objects, and means that there may be three relationships, for example, “A and/or B” may refer to three cases: a first case refers to the presence of A alone. A second case refers to the presence of both A and B. A third case refers to the presence of B alone, where A and B may be singular or plural.

In the present disclosure, “at least one” refers to one or more, and “more” in the “one or more” refers to two or more. “one or more”, “at least one of the followings”, or similar expressions thereof refer to any combination of items listed, including any combination of a singular item or multiple items. For example, “at least one of a, b, or c”, or “at least one of a, b, and c”, may each represent: a, b, c, a-b (i.e., a and b), a-c, b-c, or a-b-c, where a, b, and c may be single or plural.

In the present disclosure, a description of “A layer is formed on one side of B layer”, “A layer is formed on one side of B layer away from C layer”, or similar expressions thereof may mean that the A layer is directly formed on the side of the B layer or the side of B layer away from C layer which mean that the A layer is in direct contact with the B layer, or it may mean that the A layer is indirectly formed on the side of the B layer or the side of the B layer away from the C layer which mean that other interval structure layers may be formed between the A layer and the B layer. Similarly, “A layer is disposed on one side of B layer”, “A layer is disposed on one side of B layer away from C layer”, or similar expressions thereof may mean that the A layer is in direct contact with the B layer, or it may mean that there are other interval structure layers between the A layer and the B layer. “A layer is disposed between B layer and C layer” may mean that the A layer is in direct contact with the B layer and the A layer is in direct contact with the C layer, the A layer is in direct contact with the B layer and one or more interval structure layers are disposed between the A layer and the C layer, one or more interval structure layers are disposed between the A layer and the B layer and one or more interval structure layers are disposed between the A layer and the C layer, or one or more interval structure layers are disposed between the A layer and the B layer and the A layer is in direct contact with the C layer.

A term “substituted or unsubstituted” indicates that a defined group may or may not be substituted. When the defined group is substituted, it is understood that a hydrogen atom at any position in the defined group may be substituted with one or more substituents R. The R is selected from but not limited to a deuterium atom, a cyano group, an isocyano group, a nitro group, a halogen group, an alkyl group including 1 to 20 carbon atoms, a heterocyclyl group including 3 to 20 ring atoms, an aryl group including 6 to 20 ring atoms, a heteroaryl group including 5 to 20 ring atoms, —NR′R″, a silyl group, a carbonyl group, an alkoxycarbonyl group, an aryloxycarbonyl group, an aminoformyl group, a haloformyl group, a formyl group, an isocyanate group, a thiocyanate group, an isothiocyanate group, a hydroxyl, or a trifluoromethyl group, and the above groups may also be further substituted with art-acceptable substituents. It is understood that R′ and R″ in —NR′R″ are each independently selected from but not limited to H, a deuterium atom, a cyano group, an isocyano group, a nitro group, a halogen group, an alkyl group including 1 to 20 carbon atoms, a heterocyclyl group including 3 to 20 ring atoms, an aryl group including 6 to 20 ring atoms, a heteroaryl group including 5 to 20 ring atoms, a silyl group, a carbonyl group, an alkoxycarbonyl group, an aryloxycarbonyl group, an aminoformyl group, a haloformyl group, a formyl group, an isocyanate group, a thiocyanate group, an isothiocyanate group, a hydroxyl, or a trifluoromethyl group, and the above groups may also be further substituted with art-acceptable substituents.

A term “a heteroatom” is a non-carbon atom which may be a nitrogen atom, an oxygen atom, a sulfur atom, or the like.

A term “a number of ring atoms” refers to a number of ring atoms constituting the ring itself in a structural compound (for example, a monocyclic compound, a fused ring compound, a crosslinked compound, a carbocyclic compound, or a heterocyclic compound) obtained by atomic bonding to form a ring, that is, a number of atoms forming a ring. When the ring is substituted with a substituent, atoms contained in the substituent are not included in the ring atoms. The same applies to “a number of ring atoms” described below unless otherwise specified. For example, a number of ring atoms of a benzene ring is 6, a number of ring atoms of a naphthalene ring is 10, and a number of ring atoms of a thienyl group is 5.

A term “an aryl group” refers to an aromatic hydrocarbon group derived by removing one hydrogen atom from an aromatic ring compound. The aryl group may be a monocyclic aryl group, a fused-ring aryl group, or a polycyclic aryl group. For polycyclic ring species, at least one of which is an aromatic ring system. For example, “a substituted or unsubstituted aryl group including 6 to 20 ring atoms” refers to an aryl group including 6 to 20 ring atoms, and a hydrogen atom at any position of the aryl group may be further substituted. The aryl group includes but is not limited to a phenyl group, a biphenyl group, a terphenyl group, a naphthyl group, an anthracenyl group, a phenanthrenyl group, a fluoranthenyl group, a triphenylenyl group, a pyrenyl group, a perylenyl group, a tetraphenylenyl group, a fluorenyl group, a dinaphthylphenyl group, an acenaphthylenyl group, and derivatives thereof. It is understood that multiple aryl groups may also be interrupted by a short non-aromatic unit (for example, with non-hydrogen atoms accounting for less than 10%, such as a carbon atom, a nitrogen atom, or an oxygen atom. Specifically, systems such as acenaphthene, fluorene, 9,9-diarylfluorene, triarylamine, and diaryl ether may also be included in the definition of the aryl group.

A term “a heteroaryl group” refers to at least one carbon atom on the aryl group is replaced by a non-carbon atom. The non-carbon atom may be a nitrogen atom, an oxygen atom, a sulfur atom, or the like. For example, “a substituted or unsubstituted heteroaryl group including 5 to 20 ring atoms” refers to a heteroaryl group including 5 to 20 ring atoms. The heteroaryl group includes but is not limited to a thienyl group, a furyl group, a pyrrolyl group, a diazolyl group, a triazolyl group, an imidazolyl group, a pyridinyl group, a bipyridinyl group, a pyrimidinyl group, a triazinyl group, an acridinyl group, a pyridazinyl group, a pyrazinyl group, a quinolinyl group, an isoquinolinyl group, a quinazolinyl group, a quinoxalinyl group, a phthalazinyl group, a pyridopyrimidinyl group, a pyridopyrazinyl group, a benzothienyl group, a benzofuryl group, an indolyl group, a pyrroloimidazolyl group, a pyrrolopyrrolyl group, a thienopyrrolyl group, a thienothienyl group, a furylpyrrolyl group, a furylfuryl group, a thienofuryl group, a benzisoxazolyl group, a benzisothiazolyl group, a benzimidazolyl group, a phthalazinyl group, a phenanthridinyl group, a peridinyl group, a quinazolinone group, a dibenzothienyl group, a dibenzofuryl group, a carbazolyl group, and derivatives thereof.

A term “an alkyl group” refers to an alkyl group with a straight-chain, an alkyl group with a branched-chain and/or a cyclic alkyl group. A number of carbon atoms in the alkyl group may range from 1 to 20, from 1 to 10, or from 1 to 6. For phrases including the term, non-limiting examples of the alkyl group include methyl, ethyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-tert-butylcyclohexyl, n-heptyl, 1-methylheptyl, 2,2-dimethylheptyl, 2-ethylheptyl, 2-butylheptyl, n-octyl, tert-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc.

A term “an alkoxy group” refers to a group with a structure of “—O-alkyl group”, that is, the alkyl group as defined above is connected to other groups via an oxygen atom. For phrases including the term, suitable examples include but are not limited to a methoxy group (—O—CH₃ or —OMe), an ethoxy group (—O—CH₂CH₃ or —OEt), and a tert-butoxy group (—O—C(CH₃)₃ or -OtBu).

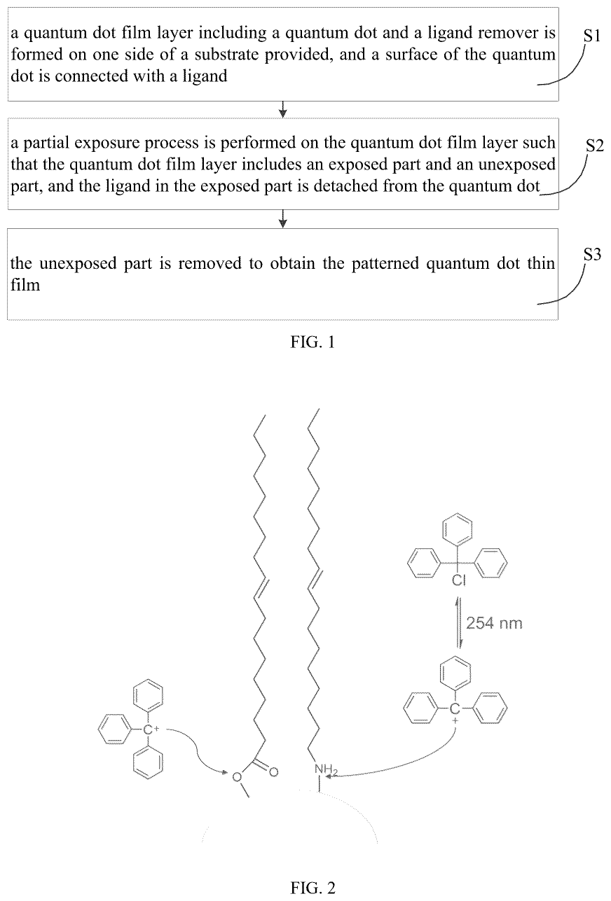

An embodiment of the present disclosure provides a preparation method for a patterned quantum dot thin film. Referring to FIG. 1, the preparation method includes step S1, step S2, and step S3.

In step S1, a quantum dot film layer including a quantum dot and a ligand remover is formed on one side of a substrate provided, and a surface of the quantum dot is connected with a ligand.

In step S2, a partial exposure process is performed on the quantum dot film layer such that the quantum dot film layer includes an exposed part and an unexposed part, and the ligand in the exposed part is detached from the quantum dot.

In step S3, the unexposed part is removed to obtain the patterned quantum dot thin film.

When the quantum dot film layer is in a wet film state or a partially cured state, prior to step S3, the preparation method further includes a step that a drying treatment is performed on the quantum dot film layer to obtain a cured quantum dot film layer.

The ligand remover is a compound represented by the following general formula (I):

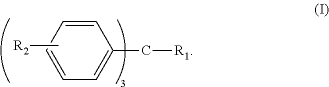

In the general formula (I), R₂ is selected from at least one of a hydrogen atom, a halogen atom, a substituted or unsubstituted alkyl group, a substituted or unsubstituted alkoxy group, a substituted or unsubstituted aryl group, and a substituted or unsubstituted heteroaryl group.

In the partial exposure process, the ligand remover in the exposure part loses R₁ to form a triphenyl carbocation with strong electrophilicity. The triphenyl carbocation bonds to the ligand of the exposed part such that the ligand of the exposed part is detached from the quantum dot, and the ligand of the unexposed part remains attached to the surface of the quantum dot. Therefore, in an elution process, the ligand is configured to be dissolved in an eluent, and the quantum dot in the exposed part may not be dissolved in the eluent due to a loss of the ligand, so that the exposed part remains on the side of the substrate, and the unexposed part is dissolved in the eluent, thereby obtaining the patterned quantum dot thin film. In an embodiment, the ligand remover is triphenylmethyl chloride, and the ligand is oleic acid and oleylamine. Referring to FIG. 2, under an illumination of light with a wavelength of 254 nm, a chlorine atom in triphenylmethyl chloride leaves to form a triphenylcarbocation. The triphenylcarbocation binds to an amino group of oleylamine such that an oleylamine ligand is detached from the quantum dot, and the triphenylcarbocation binds to a carboxyl group of oleic acid such that an oleic acid is detached from the quantum dot. A compound formed by combining the triphenyl carbocation with the ligand of the exposed part may be soluble in the eluent or insoluble in the eluent, for example, the compound is dissolved in the eluent.

Specifically, in step S1, the substrate may be a single-layer structure or a multi-layer structure. For example, the substrate is the single-layer structure, and the substrate may be a rigid substrate or a flexible substrate. A material of the rigid substrate may be, for example, glass, ceramic or metal, and a material of the flexible substrate may be, for example, at least one of polyimide, polyethylene glycol terephthalate, poly(ether-ether-ketone), polystyrene, polyethersulfone, polycarbonate, polyarylate, polyvinyl chloride, polyvinyl pyrrolidone, polyacrylate, polyetherimide, polyethylene naphthalate two formic acid glycol ester, polyphenylene sulfide or textile fiber. As another example, the substrate may be the multi-layer structure, and the substrate may be a preformed device including a supporting base and a bottom electrode.

In step S1, the quantum dot film layer may be in a wet film state, a partially cured state, or a completely cured state. For the quantum dot film layer in the wet film state and in the partially cured state, a drying treatment step needs to be added prior to the elution process to form a completely cured quantum dot film layer. The drying treatment may be performed prior to the partial exposure process or may be performed after the partial exposure process.

In some embodiments, step S1 includes step S₁ₐ that a solution including the quantum dot and the ligand remover is disposed on the side of the substrate to form the quantum dot film layer. The solution may be disposed on the side of the substrate by means of, but is not limited to, at least one of spin coating, coating, ink jet printing, blade coating, dip coating, soaking, spray coating, roll coating, or casting.

Furthermore, a solvent of the solution may be a non-polar solvent. In some embodiments, the solvent of the solution is selected from at least one of n-pentane, n-octane, n-hexane, n-heptane, n-nonane, n-decane, n-undecane, cyclohexane, or cyclopentane.

Furthermore, a concentration of the quantum dot in the solution ranges from 1 mg/mL to 1000 mg/mL, such as from 1 mg/mL to 50 mg/mL, from 50 mg/mL to 100 mg/mL, from 60 mg/mL to 150 mg/mL, from 140 mg/mL to 200 mg/mL, from 180 mg/mL to 250 mg/mL, from 220 mg/mL to 300 mg/mL, from 270 mg/mL to 400 mg/mL, from 350 mg/mL to 500 mg/mL, from 400 mg/mL to 600 mg/mL, from 500 mg/mL to 800 mg/mL, from 700 mg/mL to 900 mg/mL, or from 850 mg/mL to 1000 mg/mL.

In order to improve both a film formation quality of the quantum dot film layer and a resolution of patterning, a mass ratio of the quantum dot in the solution ranges from 1:0.01 to 1:2, such as from 1:0.01 to 1:0.03, from 1:0.02 to 1:0.04, from 1:0.03 to 1:0.05, from 1:0.04 to 1:0.06, from 1:0.05 to 1:0.07, from 1:0.06 to 1:0.08, from 1:0.07 to 1:0.09, from 1:0.1 to 1:0.12, from 1:0.11 to 1:0.13, from 1:0.12 to 1:0.14, from 1:0.13 to 1:0.15, from 1:0.14 to 1:0.16, from 1:0.15 to 1:0.17, from 1:0.16 to 1:0.18, from 1:0.17 to 1:0.19, or from 1:0.18 to 1:0.2.

In some embodiments, after step S₁ₐ, step S1 further includes step S_{1b} that a drying treatment is performed on the solution disposed on the side of the substrate to obtain a cured quantum dot film layer. The drying treatment includes all processes that enable the solution disposed on the side of the substrate to obtain higher energy and transform into a solid-state film. The drying treatment includes but is not limited to at least one of a thermal treatment or a vacuum drying treatment. The thermal treatment includes but is not limited to a constant-temperature thermal treatment or a non-constant temperature thermal treatment, for example, a temperature of the thermal treatment may change in a gradient manner. A temperature of the thermal treatment may be lower than or equal to 80 °C, a vacuum degree of the vacuum drying treatment may range from 10⁻² MPa to 10⁻⁷ MPa, and the time of the vacuum drying treatment may range from 10 minutes to 60 minutes.

In step S1, an emission color of the quantum dot includes but is not limited to red, blue, or green. The quantum dot includes but is not limited to a quantum dot with a single component, a quantum dot with a core-shell structure, an inorganic perovskite quantum dot, an organic perovskite quantum dot, or an organic-inorganic hybrid perovskite quantum dot. An average particle size of the quantum dot may range from 5 nm to 10 nm, such as 5 nm, 6 nm, 7 nm, 8 nm, 9 nm, or 10 nm.

When the quantum dot is the quantum dot with the single component or the quantum dot with the core-shell structure, a material of the quantum dot with the single component, a material of the core of the quantum dot with the core-shell structure, and a material of a shell layer of the quantum dot with the core-shell structure each independently includes but is not limited to at least one of a group II-VI compound, a group III-V compound, a group IV-VI compound, or a group I-III-VI compound. The group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe, the group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, the group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, or SnPbSTe, and the group I-III-VI compound is selected from at least one of CuInS₂, CuInSe₂, or AgInS₂. For the material of the quantum dot with the single component, the material of the core of the quantum dot with the core-shell structure, and the material of a shell layer of the quantum dot with the core-shell structure, a chemical formula provided only indicates an elemental composition and does not indicate a content of each element. For example, CdZnSe only indicates that it is composed of three elements, Cd, Zn, and Se. If the content of each element is to be indicated, it may correspondingly be CdₓZn₁₋ₓSe, where 0<x<1.

The inorganic perovskite quantum dot has a general structural formula of AMX₃. A is Cs⁺, M is a divalent metal cation including but being not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but being not limited to Cl⁻, Br⁻, or I⁻.

The organic perovskite quantum dot has a general structural formula of CMX₃. C is a formamidyl, M is a divalent metal cation including but being not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but being not limited to Cl⁻, Br⁻, or I⁻.

The organic-inorganic hybrid perovskite quantum dot has a general structural formula of BMX₃. B is an organic amine cation including but being not limited to CH₃(CH₂)ₙ₋₂NH³⁺ or NH₃(CH₂)ₙ NH₃²⁺, n is greater or equal to 2, M is a divalent metal cation including but being not limited to Pb²⁺, Sn²⁺, Cu²⁺, Ni²⁺, Cd²⁺, Cr²⁺, Mn²⁺, Co²⁺, Fe²⁺, Ge²⁺, Yb²⁺, or Eu²⁺, and X is a halogen anion including but being not limited to Cl⁻, Br⁻, or I⁻.

In step S1, the ligand is an original ligand attached to a surface of the quantum dot. In some embodiments, the ligand is selected from a ligand having a hydrocarbon chain with 6 to 30 carbon atoms. For example, the ligand is selected from at least one of a fatty amine ligand including 6 to 20 carbon atoms, a fatty acid ligand including 6 to 20 carbon atoms, and a fatty thiol ligands including 6 to 20 carbon atoms. The fatty amine ligand including 6 to 20 carbon atoms may be selected from at least one of oleylamine, butylamine, octylamine, ethylenediamine or octadecylamine, the fatty acid ligand including 6 to 20 carbon atoms may be selected from at least one of oleic acid, acetic acid, butyric acid, valeric acid, hexanoic acid, eicosanoic acid, n-decanoic acid, 10-undecenoic acid, myristic acid or stearic acid, and the fatty thiol ligands including 6 to 20 carbon atoms may be selected from at least one of ethyl mercaptan, propyl mercaptan, mercaptoethanol, octanethiol, dodecyl mercaptan or octadecanethiol.

In step S1, R₁ is selected from a group that is detached from the ligand remover in the partial exposure process. In some embodiments, a pKa value of a conjugated acid formed after the R₁ accepts a proton in water at 25 °C ranges between −10 and 9, so that the R₁ has a characteristics of easily accepting electrons and strong ability to bear negative charges, thus the R₁ is easily detached from the ligand remover. The R₁ is selected from a halogen atom, a p-toluenesulfonyl group, a p-toluenesulfonyloxy group, a mercapto group, a cyano group, an azide group, a thiocyano group or an alkoxycarbonyl group. The alkoxycarbonyl group may be, for example, a methoxycarbonyl group, an ethoxycarbonyl group, or the like.

In the general formula (I), R₂ is, for example, selected from a hydrogen atom, a halogen atom, a substituted or unsubstituted alkyl group including 1 to 10 carbon atoms, a substituted or unsubstituted aryl group including 1 to 10 carbon atoms, a substituted or unsubstituted aryl group including 6 to 20 ring atoms, or a substituted or unsubstituted heteroaryl group including 5 to 20 ring atoms.

In some embodiments, the ligand remover is selected from at least one of triphenylmethyl chloride, triphenylmethyl bromide, or triphenylmethyl iodide.

In step S3, an exposure process is performed on the quantum dot film layer by using a photomask. In some embodiments, an illumination wavelength of the partial exposure process ranges from 200 nm to 500 nm. An illumination energy of the partial exposure process ranges from 50 mJ/cm² to 6000 mJ/cm², such as from 50 mJ/cm² to 100 mJ/cm², from 100 mJ/cm² to 500 mJ/cm², from 300 mJ/cm² to 600 mJ/cm², from 500 mJ/cm² to 1000 mJ/cm², from 1000 mJ/cm² to 2000 mJ/cm², from 2000 mJ/cm² to 3000 mJ/cm², from 3000 mJ/cm² to 4000 mJ/cm², 4000 mJ/cm² to 5000 mJ/cm², or from 5000 mJ/cm² to 6000 mJ/cm².

In order to ensure that the ligand of the exposed part is sufficiently detached from the quantum dot, in some embodiments, when the illumination wavelength of the partial exposure process ranges from 200 nm to 500 nm, a molar absorbance coefficient of the ligand remover at the illumination wavelength of the partial exposure process ranges from 10 cm⁻¹M⁻¹ to 10⁵ cm⁻¹M⁻¹, such as from 10 cm⁻¹M⁻¹ to 10² cm⁻¹M⁻¹, from 10² cm⁻¹M⁻¹ to 10³ cm⁻¹M⁻¹, from 10³ cm⁻¹M⁻¹ to 10⁴ cm⁻¹M⁻¹, or from 10⁴ cm⁻¹M⁻¹ to 10⁵ cm⁻¹M⁻¹.

In some embodiments, step S3 includes a step that an elution process is performed on the quantum dot film layer with an eluent. The unexposed part is dissolved in the eluent. The eluent refers to a type of solvent that is capable of dissolving a ligand and a quantum dot having a ligand attached to a surface thereof, but does not dissolve a quantum dot having no ligand attached to a surface thereof.

In some embodiments, a dielectric constant of the eluent is less than 10. The eluent includes but is not limited to at least one of toluene, chlorobenzene, n-hexane, n-octane, n-heptane, cyclohexane, dichloromethane, chloroform and tetrahydrofuran.

The patterned quantum dot thin film may be a single layer, and a material of a quantum dot thin film includes one kind of quantum dot or multiple kinds of quantum dots. When the material of the quantum dot thin film includes multiple kinds of quantum dots, emission colors of the multiple kinds of quantum dots may be different from each other. The patterned quantum dot thin film may also have multiple layers, a material of each layer may be quantum dots of different emission colors or the same emission color, and patterns of each layer may be the same or different.

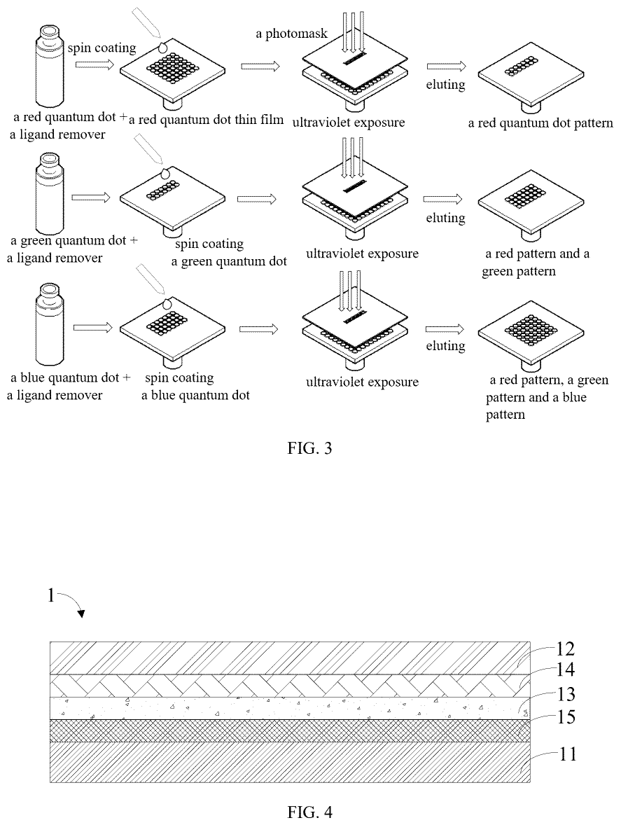

As an example, a quantum dot thin film is a single layer, and the material of the quantum dot thin film includes a red quantum dot, a green quantum dot, and a blue quantum dot. Referring to FIG. 3, a preparation method for the quantum dot thin film includes step S11, step S12, step S13, step S14, step S21, step S22, step S23, step S24, step S31, step S32, step S33, and step S34.

In step S11, a first solution including a first quantum dot and a first ligand remover is disposed on one side of a substrate provided. The first quantum dot is a red quantum dot, and a surface of the first quantum dot is connected with a first ligand.

In step S12, a drying treatment is performed on the first solution disposed on the side of the substrate to obtain a first quantum dot layer.

In step S13, a partial exposure process is performed on the first quantum dot layer such that the first quantum dot layer includes an exposed part and an unexposed part. The first ligand in the exposed part is detached from the first quantum dot.

In step S14, the first quantum dot layer is eluted by a first eluent capable of dissolving the first ligand to obtain a red quantum dot pattern.

In step S21, a second solution including a second quantum dot and a second ligand remover is disposed on a blank area of the side of the substrate. The second quantum dot is a green quantum dot, and a surface of the second quantum dot is connected with a second ligand.

In step S22, a drying treatment is performed on the second solution disposed on the side of the substrate to obtain a second quantum dot layer. The second quantum dot layer is disposed on the same layer as the red quantum dot pattern.

In step S23, a partial exposure process is performed on the second quantum dot layer such that the second quantum dot layer includes an exposed part and an unexposed part. The second ligand in the exposed part is detached from the second quantum dot.

In step S24, the second quantum dot layer is eluted by a second eluent capable of dissolving the second ligand to obtain a green quantum dot pattern.

In step S31, a third solution including a third quantum dot and a third ligand remover is disposed on a blank area of the side of the substrate. The third quantum dot is a blue quantum dot, and a surface of the third quantum dot is connected with a third ligand.

In step S32, a drying treatment is performed on the third solution disposed on the side of the substrate to obtain a third quantum dot layer. The third quantum dot layer is disposed on the same layer as the red quantum dot pattern and the green quantum dot pattern.

In step S33, a partial exposure process is performed on the third quantum dot layer such that the third quantum dot layer includes an exposed part and an unexposed part. The third ligand in the exposed part is detached from the third quantum dot.

In step S34, the third quantum dot layer is eluted by a third eluent capable of dissolving the third ligand to obtain a blue quantum dot pattern. The quantum dot thin film formed has a single-layer structure, and the quantum dot thin film includes the red quantum dot pattern, the green quantum dot pattern and the blue quantum dot pattern disposed in the same layer.

As another example, a quantum dot thin film includes a first patterned quantum dot layer, a second patterned quantum dot layer, and a third patterned quantum dot layer disposed in stack. A material of the first patterned quantum dot layer is a red quantum dot, a material of the second patterned quantum dot layer is a green quantum dot, and a material of the third patterned quantum dot layer is a blue quantum dot. A preparation method for the thin quantum dot film includes step S101, step S102, step S103, step S104, step S201, step S202, step S203, step S204, step S301, step S302, step S303, and step S304.

In step S101, a first solution including a first quantum dot and a first ligand remover is disposed on one side of a substrate provided. The first quantum dot is a red quantum dot, and a surface of the first quantum dot is connected with a first ligand.

In step S102, a drying treatment is performed on the first solution disposed on the side of the substrate to obtain a first quantum dot layer.

In step S103, a partial exposure process is performed on the first quantum dot layer such that the first quantum dot layer includes an exposed part and an unexposed part. The first ligand in the exposed part is detached from the first quantum dot.

In step S104, the first quantum dot layer is eluted by a first eluent capable of dissolving the first ligand to obtain a patterned first quantum dot layer.

In step S201, a second solution including a second quantum dot and a second ligand remover is disposed on one side of the first quantum dot layer away from the substrate. The second quantum dot is a green quantum dot, and a surface of the second quantum dot is connected with a second ligand.

In step S202, a drying treatment is performed on the second solution disposed on the side of the first quantum dot layer away from the substrate to obtain a second quantum dot layer.

In step S203, a partial exposure process is performed on the second quantum dot layer such that the second quantum dot layer includes an exposed part and an unexposed part. The second ligand in the exposed part is detached from the second quantum dot.

In step S204, the second quantum dot layer is eluted by a second eluent capable of dissolving the second ligand to obtain a green quantum dot pattern.

In step S301, a third solution including a third quantum dot and a third ligand remover is disposed on one side of the second quantum dot layer away from the first quantum dot layer. The third quantum dot is a blue quantum dot, and a surface of the third quantum dot is connected with a third ligand.

In step S302, a drying treatment is performed on the third solution disposed on the side of the second quantum dot layer away from the first quantum dot layer to obtain a third quantum dot layer.

In step S303, a partial exposure process is performed on the third quantum dot layer such that the third quantum dot layer includes an exposed part and an unexposed part. The third ligand in the exposed part is detached from the third quantum dot.

In step S304, the third quantum dot layer is eluted by a third eluent capable of dissolving the third ligand to obtain a patterned third quantum dot layer.

The first ligand, the second ligand, and the third ligand each refers to a description of the ligand mentioned previously. The first eluent, the second eluent, and the third eluent each refers to a description of the eluent mentioned previously.

Conventional methods for patterning a quantum dot thin film mainly include a photolithography method, an electron beam etching method, an inkjet printing method and a nanoimprinting method. However, these methods are difficult to take into account indicators such as improving pattern resolution, universality and reducing manufacturing costs. Especially, compared with a photoluminescence quantum yield of a thin quantum dot film before patterning, a photoluminescence quantum yield of the quantum dot thin film may decrease significantly. The photolithography method uses photoresist which may contaminate and degrade quantum dots, and a solvent used to remove the photoresist may dissolve a deposited quantum dot layer. The electron beam etching method utilizes a high-energy electron beam or X-ray to etch pattern, but the high-energy electron beam or X-ray may cause irreversible damage to quantum dots. A patterned quantum dot thin film prepared by the inkjet printing method is prone to a coffee ring phenomenon, the inkjet printing method has strict requirements for a viscosity and a concentration of ink, and the inkjet printing method has a problem of difficult precise deposition which makes it difficult for a pattern resolution of a quantum dot thin film prepared by the inkjet printing method to reach less than 50 microns. Compared with the photolithography method, the electron beam etching method, and the inkjet printing method, a quantum dot thin film prepared by the nanoimprinting method has a higher pattern resolution, but has some problems such as a high manufacturing cost, poor flexibility and unstable pattern quality.

The preparation method of embodiments in the present disclosure is based on surface chemistry of quantum dots and a colloid stabilization mechanism, conducts chemical design and modification of original ligands of the quantum dots, and utilizes photosensitive chemistry to construct a patterning method with high precision and high performance. Specifically, the preparation method includes: a quantum dot film layer including a ligand remover with a structure represented by the general formula (I) and a quantum dot with a ligand attached to a surface thereof is disposed on one side of a substrate, then a partial exposure process is performed on the quantum dot film layer, followed by an elution process being performed on the quantum dot film layer to obtain a patterned quantum dot thin film. The preparation method may prepare quantum dots with different structural compositions to form a patterned film, and a pattern resolution may reach 4 microns. The preparation method has advantages of high pattern resolution, high universality, a simple preparation process, and suitability for large-scale industrial production.

Moreover, a whole patterning process does not involve a process of damaging a quantum dot such as ligand exchange, so that a photoelectric property of the quantum dot before and after patterning may not be significantly changed. For example, a photoluminescence quantum yield of a red quantum dot remains the same before and after patterning, a photoluminescence quantum yield of a green quantum dot after patterning is 90% of that before patterning, and for a blue quantum dot with poor stability and sensitive surfaces, a photoluminescence quantum yield of the blue quantum dot after patterning is 70% of that before patterning.

An embodiment of the present disclosure provides a photoelectric device. Referring to FIG. 4, a photoelectric device 1 includes an anode 11, a cathode 12 disposed opposite the anode 11, and a light-emitting layer 13 disposed between the anode 11 and the cathode 12. The light-emitting layer 13 includes a plurality of quantum dot layers, at least one of the quantum dot layers is prepared by the preparation method for a patterned quantum dot thin film described in any one of embodiments of the present disclosure, and a material of each of the quantum dot layers includes a quantum dot with at least one emission color. “A plurality of quantum dot layers” refers to one or more quantum dot layers, a number of quantum dot layers in the light-emitting layer 13 may be one, two, three, four, or more.

In the photoelectric device 1, materials of the anode 11 and the cathode 12 are each independently selected from at least one of a metal, a carbon material, or a first metal oxide. The metal is selected from at least one of Al, Ag, Cu, Mo, Au, Ba, Ca or Mg, the carbon material is selected from at least one of graphite, carbon nanotube, graphene or carbon fiber, and the first metal oxide may be a doped or undoped metal oxide. For example, the first metal oxide is selected from at least one of indium tin oxide (ITO), fluorine-doped tin oxide (FTO), antimony tin oxide (ATO), aluminium-doped zinc oxide (AZO), gallium-doped zinc oxide (GZO), indium-doped zinc oxide (IZO), magnesium-doped zinc oxide (IZO), or magnesium-doped zinc oxide. The anode 11 or the cathode 12 may also be selected from a composite electrode with the metal sandwiched between doped or undoped transparent metal oxides. The composite electrode includes but is not limited to at least one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, or TiO₂/Al/TiO₂. For example, a thickness of the anode 11 ranges from 20 nm to 200 nm, and a thickness of the cathode 12 ranges from 20 nm to 200 nm.

In order to further improve a photoelectric performance and a lifetime of the photoelectric device 1, in some embodiments, referring to FIG. 3, the photoelectric device 1 further includes an electron functional layer 14 disposed between the cathode 12 and the light-emitting layer 13. The electron functional layer 14 includes an electron transport layer and/or an electron injection layer. When the electron functional layer 14 includes the electron transport layer and the electron injection layer, the electron transport layer is closer to the light-emitting layer 13 than the electron injection layer, and the electron injection layer is closer to the cathode 12 than the electron transport layer. For example, a thickness of the electron functional layer 14 ranges from 10 nm to 120 nm.

In some embodiments, the electron functional layer 14 includes the electron transport layer, and a material of the electron transport layer includes a second metal oxide. The second metal oxide is an undoped metal oxide or a doped metal oxide. The second metal oxide includes but is not limited to at least one of ZnO, TiO₂, SnO₂, BaO, Ta₂O₃, ZrO₂, TiLiO, ZnGaO, ZnAlO, ZnMgO, ZnSnO, ZnLiO, InSnO, AlZnO, ZnOCl, ZnOF, or ZnMgLiO. For a doped second metal oxide, a chemical formula provided only indicates an elemental composition and does not indicate a content of each element. For example, ZnMgO only indicates that the doped second metal oxide is composed of three elements: Zn, Mg, and O. An average particle size of the second metal oxide may range from 2 nm to 15 nm, such as 2 nm, 3 nm, 4 nm, 5 nm, 6 nm, 7 nm, 8 nm, 9 nm, 10 nm, 11 nm, 12 nm, 13 nm, 14 nm, or 15 nm. For example, a thickness of the electron transport layer ranges from 10 nm to 60 nm.

In some embodiments, the electron functional layer 14 includes the electron injection layer, and a material of the electron injection layer includes but is not limited to at least one of an alkali metal halide, an alkali metal organic complex, or an organophosphine compound. The organophosphine compound includes but is not limited to at least one of an organic phosphorus oxide, an organic thiophosphine compound, or an organic selenophosphine compound. For example, a thickness of the electron injection layer ranges from 10 nm to 60 nm.

In order to further improve the photoelectric performance and the lifetime of the photoelectric device 1, in some embodiments, referring to FIG. 3, the photoelectric device 1 further includes further includes a hole functional layer 15 disposed between the light-emitting layer 13 and the anode 11. The hole functional layer 15 includes a hole injection layer and/or a hole transport layer. When the hole functional layer 15 includes the hole injection layer and the hole transport layer, the hole injection layer is closer to the anode 11 than the hole transport layer, and the hole transport layer is closer to the light-emitting layer 13 than the hole injection layer. For example, a thickness of the hole functional layer 15 ranges from 10 nm to 120 nm.

In one embodiment, a thickness of the hole injection layer ranges from 10 nm to 60 nm, and a material of the hole injection layer includes but is not limited to at least one of poly(3,4-ethylenedioxythiophene)-poly(styrenesulfonate), copper(II) phthalocyanine, titanyl phthalocyanine, 4,4′,4″-tris(N-3-methylphenyl-N-phenylamino)triphenylamine, 4,4′,4″-tris[2-naphthyl(phenyl)amino]triphenylamine, hexaazatriphenylenehexacabonitrile, 2,3,5,6-tetrafluoro-7,7,8,8-tetracyanoquinodimethane, a transition metal oxide, or a transition metal chalcogenide. The transition metal oxide includes but is not limited to at least one of an oxide of nickel, an oxide of molybdenum, an oxide of tungsten, an oxide of vanadium, an oxide of chromium, or an oxide of copper, and the transition metal chalcogenide includes but is not limited to at least one of a sulfide of molybdenum, a selenide of molybdenum, a sulfide of tungsten, a selenide of tungsten, or a sulfide of copper.

In one embodiment, a thickness of the hole transport layer ranges from 10 nm to 100 nm, a material of the hole injection layer includes but is not limited to at least one of poly(9,9-dioctylfluorene-co-N-(4-butylphenyl)diphenylamine) (TFB, CAS: 220797-16-0), poly(3-hexylthiophene-2,5-diyl) (CAS: 104934-50-1), poly(N-vinylcarbazole) (CAS: 25067-59-8), poly[N,N′-bis(4-butylphenyl)-N,N′-bis(phenyl)-benzi (Poly-TPD, CAS: 472960-35-3), poly(N,N′-bis(4-butylphenyl)-N,N′-diphenyl-1,4-benzenediamine-co-9,9-dioctylfluorene (PFB, CAS: 223569-28-6), 4,4′,4″-tris(carbazol-9-yl)-triphenylamine (TCTA, CAS: 139092-78-7), 4,4′-bis(N-carbazolyl)-1,1′-biphenyl (CBP, CAS: 58328-31-7), N,N′-bis(3-methylphenyl)-N,N′-bis(phenyl)benzidine (TPD, CAS: 65181-78-4), N,N′-bis-(1-naphthalenyl)-N,N′-bis-phenyl-(1,1′-biphenyl)-4,4′-diamine (NPB, CAS: 123847-85-8), poly(3,4-ethylenedioxythiophene)-poly(styrenesulfonate), doped or undoped graphene, C60, NiO, MoO₃, WO₃, V₂O₅, CrO₃, CuO, or P-type gallium nitride.

In addition to the light-emitting layer, a method for preparing each layer in the photoelectric device includes but is not limited to a solution method and a deposition method. The solution method includes but is not limited to spin coating, coating, ink jet printing, blade coating, dip coating, soaking, spray coating, roll coating, or casting. The deposition method includes a chemical method and a physical method. The chemical method includes a chemical vapor deposition method, a continuous ion layer adsorption and reaction method, an anodic oxidation method, an electrolytic deposition method, or a co-precipitation method. The physical method includes but not limited to a physical coating method and a solution method. The physical coating method includes but not limited to a thermal evaporation coating method, an electron beam evaporation coating method, a magnetron sputtering method, a multi-arc ion coating method, a physical vapor deposition method, an atomic layer deposition method, or a pulsed laser deposition method. When a layer is prepared by the solution method, it is necessary to add a drying process to convert a wet film into a cured film.

A method for preparing the photoelectric device may also include other steps, for example, after preparing each layer of the photoelectric device, it is necessary to perform an encapsulating process on the photoelectric device.

An embodiment of the present disclosure provides an electronic device including the photoelectric device according to any one of the embodiments of the present disclosure. The electronic device may be any electronic product with a display function, including but being not limited to a smartphone, a tablet computer, a notebook computer, a digital camera, a digital video camera, a smart wearable device, a smart weighing electronic scale, a vehicle display, a television or an electronic book. The smart wearable device may be, for example, a smart bracelet, a smart watch, a virtual reality helmet, or the like.

The following is a detailed description of technical proposals and beneficial effects of the present disclosure through specific embodiments and comparative examples. The following embodiments are only part of implementation examples of the present disclosure, and are not specifically limited to the present disclosure.

### Example 1

The present embodiment provides a preparation method for a patterned quantum dot thin film and a patterned quantum dot thin film. A material of the patterned quantum dot thin film includes a red quantum dot CdSe (core)/CdS (shell). A surface of the red quantum dot CdSe/CdS is connected with an oleylamine ligand. A method for preparing the red quantum dot CdSe/CdS is carried out with reference to a literature (Chaodan Pu, Xingliang Dai, Yufei Shu, et al. Electrochemically-stable ligands bridge the photoluminescence-electroluminescence gap of quantum dots [J]. Nat Commun, 2020, 11(1): 937).

The preparation method for the patterned quantum dot thin film includes step S1.1, step S1.2, step S1.3, and step S1.4.

In step S1.1, A glass substrate was ultrasonically cleaned by deionized water for 15 minutes, acetone for 15 minutes, ethanol for 15 minutes and isopropanol for 15 minutes sequentially, and an ultraviolet-ozone surface treatment was performed on the glass substrate for 5 minutes after drying. A first solution including the red quantum dot CdSe/CdS and triphenylmethyl chloride was spin-coated on one side of the glass substrate. A solvent of the first solution was methylbenzene, a concentration of the red quantum dot CdSe/CdS in the first solution was 30 mg/mL, and a concentration of triphenylmethyl chloride in the first solution was 2 mg/mL.

In step S1.2, a constant-temperature thermal treatment was performed on the first solution disposed on the side of the glass substrate at 80 °C for 10 minutes to obtain a red quantum dot thin film with a thickness of 20 nm.

In step S1.3, a partial exposure process was performed on the red quantum dot thin film by using a photomask, so that the red quantum dot film included an exposed part and an unexposed part, and the ligand was detached from the red quantum dot thin film. In the partial exposure process, a light source was ultraviolet light with a wavelength of 254 nm, an illumination energy was 1000 mJ/cm², and the illumination time was 40 seconds.

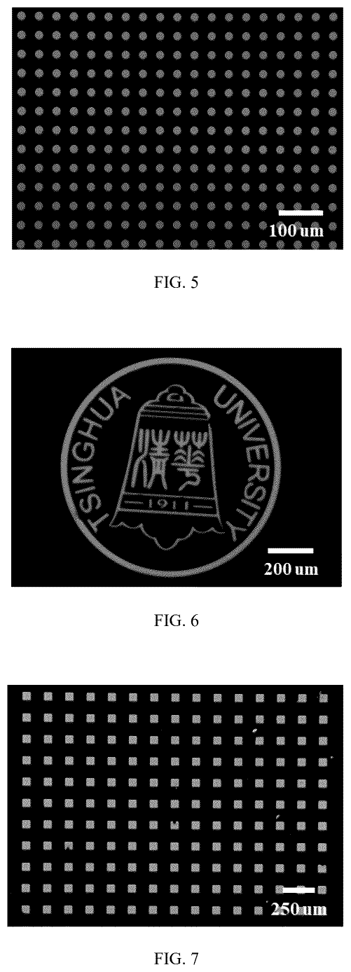

In step S1.4, the red quantum dot thin film after the partial exposure process was soaked in methylbenzene, so that the unexposed part was dissolved in methylbenzene, and the exposed part remained on the side of the glass substrate. After a pattern appeared, a surface of the red quantum dot thin film was blown dry with nitrogen to obtain a patterned red quantum dot thin film as shown in FIG. 5. The patterned red quantum thin film exhibited a circular array pattern of quantum dots emitting red light, and a diameter of each circle was 20 microns.

### Example 2

The present embodiment provides a preparation method for a patterned quantum dot thin film and a patterned quantum dot thin film. A material of the patterned quantum dot thin film includes a green quantum dot CdSe (core)/Cd₁₋ₓZnₓSe_{1-y}S_{y} (middle shell)/ZnS (the outermost shell). A surface of the green quantum dot CdSe/Cd₁₋ₓZnₓSe_{1-y}S_{y}/ZnS is connected with an oleic acid ligand. A method for preparing the green quantum dot CdSe/Cd₁₋ₓZnₓSe_{1-y}S_{y}/ZnS is carried out with reference to a literature (Himchan Cho, Jia-Ahn Pan, Haoqi Wu, et al. Direct optical patterning of quantum dot light-emitting diodes via in situ ligand exchange [J]. Adv Mater, 2020, 32(46): 2003805).

The preparation method for the patterned quantum dot thin film includes step S2.1, step S2.2, step S2.3, and step S2.4.

In step S2.1, A glass substrate was ultrasonically cleaned by deionized water for 15 minutes, acetone for 15 minutes, ethanol for 15 minutes and isopropanol for 15 minutes sequentially, and an ultraviolet-ozone surface treatment was performed on the glass substrate for 5 minutes after drying. A second solution including the green quantum dot CdSe/Cd₁₋ₓZnₓSe_{1-y}S_{y}/ZnS and triphenylmethyl chloride was spin-coated on one side of the glass substrate. A solvent of the second solution was methylbenzene, a concentration of the green quantum dot CdSe/Cd₁₋ₓZnₓSe_{1-y}S_{y}/ZnS in the second solution was 20 mg/mL, and a concentration of triphenylmethyl chloride in the second solution was 2 mg/mL.

In step S2.2, a constant-temperature thermal treatment was performed on the second solution disposed on the side of the glass substrate at 80 °C for 10 minutes to obtain a green quantum dot thin film with a thickness of 20 nm.

In step S2.3, a partial exposure process was performed on the green quantum dot thin film by using a photomask, so that the green quantum dot thin film included an exposed part and an unexposed part. In the partial exposure process, a light source was ultraviolet light with a wavelength of 254 nm, an illumination energy was 1000 mJ/cm², and the illumination time was 40 seconds.

In step S2.4, the green quantum dot thin film after the partial exposure process was soaked in methylbenzene, so that the unexposed part was dissolved in methylbenzene, and the exposed part remained on the side of the glass substrate. After a pattern appeared, a surface of the green quantum dot thin film was blown dry with nitrogen to obtain a patterned green quantum thin film as shown in FIG. 6. The patterned green quantum thin film exhibited a pattern of “Tsinghua University Emblem”, demonstrating that the preparation method in the embodiment has an ability to construct a complex pattern.

### Example 3

The present embodiment provides a preparation method for a patterned quantum dot thin film and a patterned quantum dot thin film. A material of the patterned quantum dot thin film includes a blue quantum dot Cd₁₋ₓZnₓS (core)/ZnS (shell). A surface of the blue quantum dot Cd₁₋ₓZnₓS/ZnS is connected with an oleic acid ligand. A method for preparing the blue quantum dot Cd₁₋ₓZnₓS/ZnS is carried out with reference to a literature (Wan Ki Bae, Min Ki Nam, Kookheon Char, et al. Gram-Scale One-Pot Synthesis of Highly Luminescent Blue Emitting Cd1−xZnxS/ZnS Nanocrystals [J]. Chem. Mater, 2008, 20(16), 5307-13).

The preparation method for the patterned quantum dot thin film includes step S3.1, step S3.2, step S3.3, and step S3.4.

In step S3.1, A glass substrate was ultrasonically cleaned by deionized water for 15 minutes, acetone for 15 minutes, ethanol for 15 minutes and isopropanol for 15 minutes sequentially, and an ultraviolet-ozone surface treatment was performed on the glass substrate for 5 minutes after drying. A third solution including the blue quantum dot Cd₁₋ₓZnₓS/ZnS and triphenylmethyl chloride was spin-coated on one side of the glass substrate. A solvent of the third solution was methylbenzene, a concentration of the blue quantum dot Cd₁₋ₓZnₓS/ZnS in the third solution was 20 mg/mL, and a concentration of triphenylmethyl chloride in the third solution was 0.5 mg/mL.

In step S3.2, a constant-temperature thermal treatment was performed on the third solution disposed on the side of the glass substrate at 80 °C for 10 minutes to obtain a blue quantum dot thin film with a thickness of 20 nm.

In step S3.3, a partial exposure process was performed on the blue quantum dot thin film by using a photomask, so that the blue quantum dot thin film included an exposed part and an unexposed part. In the partial exposure process, a light source was ultraviolet light with a wavelength of 254 nm, an illumination energy was 1000 mJ/cm², and the illumination time was 40 seconds.

In step S3.4, the blue quantum dot thin film after the partial exposure process was soaked in methylbenzene, so that the unexposed part was dissolved in methylbenzene, and the exposed part remained on the side of the glass substrate. After a pattern appeared, a surface of the blue quantum dot thin film was blown dry with nitrogen to obtain a patterned blue quantum thin film as shown in FIG. 7. The patterned blue quantum thin film exhibited a square array pattern of quantum dots emitting blue light, and a side length of each square was 60 microns.

### Example 4

The present embodiment provides a preparation method for a patterned quantum dot thin film and a patterned quantum dot thin film. The patterned quantum dot thin film has a single-layer structure. A material of the patterned quantum dot thin film includes the same red quantum dot CdSe/CdS with an oleylamine ligand attached to a surface thereof as that of Example 1, the same green quantum dot CdSe/Cd₁₋ₓZnₓSe_{1-y}S_{y}/ZnS with an oleic acid ligand attached to a surface thereof as that of Example 2, and the same blue quantum dot Cd₁₋ₓZnₓS/ZnS with an oleic acid ligand attached to a surface thereof as that of Example 3.

The preparation method for the patterned quantum dot thin film is shown in FIG. 3, and the preparation method includes step S4.11, step S4.12, step S4.13, step S4.14, step S4.21, step S4.22, step S4.23, step S4.24, step S4.31, step S4.32, step S4.33, and step S4.34.

In step S4.11, a glass substrate was ultrasonically cleaned by deionized water for 15 minutes, acetone for 15 minutes, ethanol for 15 minutes and isopropanol for 15 minutes sequentially, and an ultraviolet-ozone surface treatment was performed on the glass substrate for 5 minutes after drying. A first solution including the red quantum dot CdSe/CdS and triphenylmethyl chloride was spin-coated on one side of the glass substrate which is a first surface. A solvent of the first solution was methylbenzene, a concentration of the red quantum dot CdSe/CdS in the first solution was 30 mg/mL, and a concentration of triphenylmethyl chloride in the first solution was 2 mg/mL.

In step S4.12, a constant-temperature thermal treatment was performed on the first solution disposed on the side of the glass substrate at 80 °C for 10 minutes to obtain a red quantum dot layer with a thickness of 20 nm.

In step S4.13, a partial exposure process was performed on the red quantum dot layer by using a photomask, so that the red quantum dot layer included an exposed part and an unexposed part. In the partial exposure process, a light source was ultraviolet light with a wavelength of 254 nm, an illumination energy was 1000 mJ/cm², and the illumination time was 40 seconds.

In step S4.14, the red quantum dot layer after the partial exposure process was soaked in methylbenzene, so that the unexposed part was dissolved in methylbenzene, and the exposed part remained on the side of the glass substrate. After a pattern appeared, the pattern was blown dry with nitrogen to obtain a glass substrate having a red light-emitting array pattern formed on a surface thereof.

In step S4.21, a second solution including the green quantum dot CdSe/Cd₁₋ₓZnₓSe_{1-y}S_{y}/ZnS and triphenylmethyl chloride was spin-coated on the first surface of the glass substrate. A solvent of the second solution was methylbenzene, a concentration of the green quantum dot CdSe/Cd₁₋ₓZnₓSe_{1-y}S_{y}/ZnS in the second solution was 20 mg/mL, and a concentration of triphenylmethyl chloride in the second solution was 2 mg/mL. The second solution was spin-coated on a blank area on the first surface without the red light-emitting array.

In step S4.22, a constant-temperature thermal treatment was performed on the second solution disposed on the side of the glass substrate at 80 °C for 10 minutes to obtain a green quantum dot layer with a thickness of 20 nm.

In step S4.23, a partial exposure process was performed on the green quantum dot layer by using a photomask, so that the green quantum dot layer included an exposed part and an unexposed part. In the partial exposure process, a light source was ultraviolet light with a wavelength of 254 nm, an illumination energy was 1000 mJ/cm², and the illumination time was 40 seconds.

In step S4.24, the green quantum dot layer after the partial exposure process was soaked in methylbenzene, so that the unexposed part was dissolved in methylbenzene, and the exposed part remained on the side of the glass substrate. After a pattern appeared, the pattern was blown dry with nitrogen to obtain a glass substrate having the red light-emitting array pattern, a green light-emitting array pattern, and a blue light-emitting array pattern formed on the surface thereof.

In step S4.31, a third solution including the blue quantum dot Cd₁₋ₓZnₓS/ZnS and triphenylmethyl chloride was spin-coated on the first surface of the glass substrate. A solvent of the third solution was methylbenzene, a concentration of the blue quantum dot Cd₁₋ₓZnₓS/ZnS in the third solution was 20 mg/mL, and a concentration of triphenylmethyl chloride in the third solution was 0.5 mg/mL. The third solution was spin-coated on a blank area on the first surface without the red light-emitting array and the green light-emitting array.

In step S4.32, a constant-temperature thermal treatment was performed on the third solution disposed on the side of the glass substrate at 80 °C for 10 minutes to obtain a blue quantum dot layer with a thickness of 20 nm.

In step S4.33, a partial exposure process was performed on the blue quantum dot layer by using a photomask, so that the blue quantum dot layer included an exposed part and an unexposed part. In the partial exposure process, a light source was ultraviolet light with a wavelength of 254 nm, an illumination energy was 1000 mJ/cm², and the illumination time was 40 seconds.

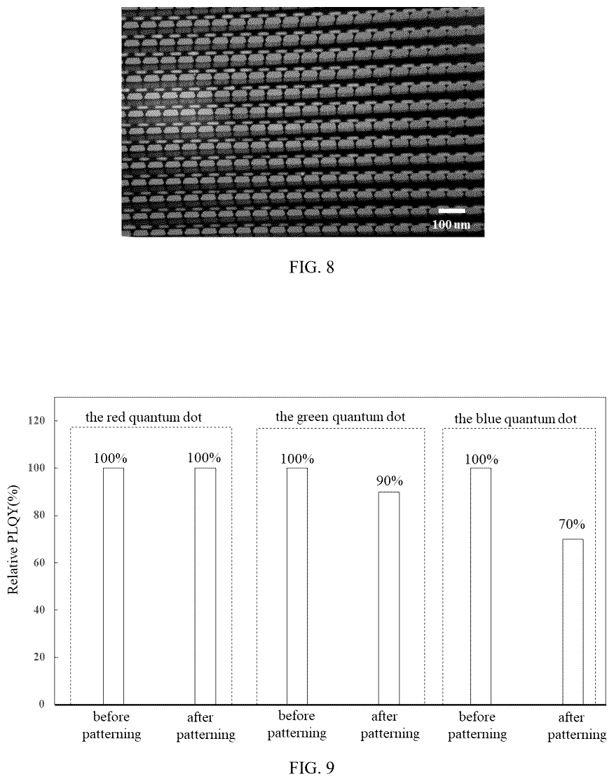

In step S4.34, the blue quantum dot layer after the partial exposure process was soaked in methylbenzene, so that the unexposed part was dissolved in methylbenzene, and the exposed part remained on the side of the glass substrate. After a pattern appeared, the pattern was blown dry with nitrogen to obtain a glass substrate having the red light-emitting array pattern, the green light-emitting array pattern, and a blue light-emitting array pattern formed on the surface thereof. Referring to FIG. 8, a quantum dot thin film is formed of the red light-emitting array pattern, the green light-emitting array pattern, and the blue light-emitting array pattern.

During a process of preparing the quantum dot thin film, photoluminescence quantum yields of the red quantum dot layer, the green quantum dot layer and the blue quantum dot layer before the partial exposure process were respectively detected and analyzed, and photoluminescence quantum yields of the red light-emitting array pattern, the green light-emitting array pattern, and the blue light-emitting array pattern were respectively detected and analyzed. Referring to FIG. 9, a photoluminescence quantum yield of the red quantum dot remains the same before and after patterning, a photoluminescence quantum yield of the green quantum dot after patterning is 90% of that before patterning, and a photoluminescence quantum yield of the blue quantum dot after patterning is 70% of that before patterning. It is demonstrated that the preparation method of the embodiment has less damage to quantum dots, so that photoelectric properties of quantum dots before and after patterning are not significantly changed, and the red quantum dot, the green quantum dot and the blue quantum dot before and after patterning may have high retention rates of fluorescence properties.

### Example 5

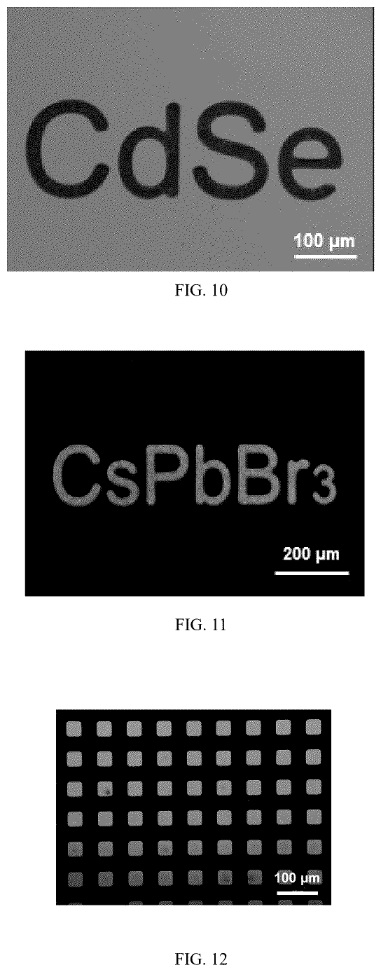

The present embodiment provides a patterned quantum dot thin film. A pattern of the patterned quantum dot thin film is shown in FIG. 10. A material of the patterned quantum dot thin film includes a green quantum dot CdSe without a core-shell structure, and a surface of the green quantum dot CdSe is connected with an oleic acid ligand and an oleylamine ligand.

Compared with the preparation method for the patterned quantum dot thin film in Example 2, an only difference of the preparation method in the present embodiment was that the green quantum dot CdSe/Cd₁₋ₓZnₓSe_{1-y}S_{y}/ZnS with the oleic acid ligand attached to a surface thereof was replaced with “the green quantum dot CdSe with an oleic acid ligand and an oleylamine ligand attached to a surface thereof”.

### Example 6

The present embodiment provides a patterned quantum dot thin film. A pattern of the patterned quantum dot thin film is shown in FIG. 11. A material of the patterned quantum dot thin film includes a perovskite quantum dot CsPbBr3. An emission color of the perovskite quantum dot CsPbBr3 is red, and a surface of the perovskite quantum dot CsPbBr3 is connected with an oleic acid ligand and an oleylamine ligand.

Compared with the preparation method for the patterned quantum dot thin film in Example 1, an only difference of the preparation method in the present embodiment was that the red quantum dot CdSe/CdS with the oleylamine ligand attached to a surface thereof was replaced with “the perovskite quantum dot CsPbBr3 with the oleic acid ligand and the oleylamine ligand attached to a surface thereof”.

### Example 7

The present embodiment provides a patterned quantum dot thin film. A pattern of the patterned quantum dot thin film is shown in FIG. 12. A material of the patterned quantum dot thin film includes a quantum dot lnP (core)/ZnS (shell). An emission color of the quantum dot lnP/ZnS is red, and a surface of the quantum dot lnP/ZnS is connected with an oleic acid ligand.

Compared with the preparation method for the patterned quantum dot thin film in Example 1, an only difference of the preparation method in the present embodiment was that the red quantum dot CdSe/CdS with the oleylamine ligand attached to a surface thereof was replaced with “the quantum dot lnP/ZnS with the oleic acid ligand attached to a surface thereof”.

### Example 8

The present embodiment provides a patterned quantum dot thin film. A pattern of the patterned quantum dot thin film is shown in FIG. 5. A material of the patterned quantum dot thin film includes the same red quantum dot CdSe/CdS with an oleylamine ligand attached to a surface thereof as that of Example 1.

Compared with the preparation method for the patterned quantum dot thin film in Example 1, an only difference of the preparation method in the present embodiment was that “triphenylchloromethane” was replaced with “triphenylacetonitrile having CAS No. 6639-43-6”.

### Example 9

The present embodiment provides a patterned quantum dot thin film. A pattern of the patterned quantum dot thin film is shown in FIG. 5. A material of the patterned quantum dot thin film includes the same red quantum dot CdSe/CdS with an oleylamine ligand attached to a surface thereof as that of Example 1.

Compared with the preparation method for the patterned quantum dot thin film in Example 1, an only difference of the preparation method in the present embodiment was that “triphenylchloromethane” was replaced with “a compound having CAS No. 42756-18-3”.

### Example 10

The present embodiment provides a patterned quantum dot thin film. A pattern of the patterned quantum dot thin film is shown in FIG. 5. A material of the patterned quantum dot thin film includes the same red quantum dot CdSe/CdS with an oleylamine ligand attached to a surface thereof as that of Example 1.

Compared with the preparation method for the patterned quantum dot thin film in Example 1, an only difference of the preparation method in the present embodiment was that “triphenylchloromethane” was replaced with “triphenylmethyl mercaptan having CAS No. 3695-77-0”.

### Example 11

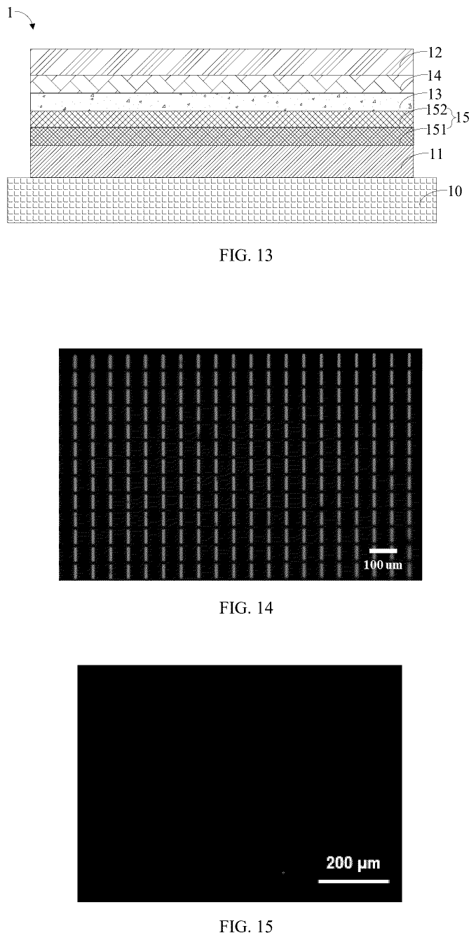

The present embodiment provides a photoelectric device and a preparation method thereof. The photoelectric device is a quantum dot light-emitting diode with an upright structure. Referring to FIG. 13, the photoelectric device 1 includes a substrate 10, an anode 11, a hole functional layer 15, a light-emitting layer 13, an electron functional layer 14 and a cathode 12 disposed sequentially in stack. The hole functional layer 15 is formed of a hole injection layer 151 and a hole transport layer 152 disposed in stack, and the hole injection layer 151 is closer to the anode 11 than the hole transport layer 152. The electron functional layer 14 is an electron transport layer.

Materials and thicknesses of each layer in the photoelectric device 1 are as follows:

A material of the substrate 10 is glass, and a thickness of the substrate 10 is 2 mm.

A material of the anode 11 is ITO, and a thickness of the anode 11 is 50 nm. A material of the cathode 12 is aluminium, and a thickness of the cathode 12 is 100 nm.

A material of the hole injection layer 151 is PEDOT:PSS, and a thickness of the hole injection layer 151 is 25 nm.

A material of the hole transport layer 152 is TFB, and a thickness of the hole transport layer 152 is 35 nm.

A material of the light-emitting layer 13 is a red quantum dot CdSe/CdS with the oleylamine ligand attached to a surface thereof, a total luminescent area is 2 cm², the light-emitting layer 13 is a red light-emitting array structure in which each small pixel has a size of 10 μm×50 m as shown in FIG. 14, and a thickness of the light-emitting layer 13 is 20 nm.

A material of the electron functional layer 14 is a nano-ZnO with an average particle size of 20 nm, and a thickness of the electron functional layer 14 is 40 nm.

A method for preparing the photoelectric device includes step S11.1, step S11.2, step S11.3, step S11.4, step S11.5, and step S11.6.

In step S11.1, ITO was sputtered on one side of the substrate to obtain an ITO layer. A surface of the ITO layer was wiped with a cotton swab dipped in a small amount of soapy water to remove visible impurities on the surface. The substrate including the ITO layer was ultrasonically cleaned by deionized water for 15 minutes, acetone for 15 minutes, ethanol for 15 minutes and isopropyl alcohol for 15 minutes sequentially, and after drying, the substrate including the anode was obtained by an ultraviolet-ozone surface treatment for 5 minutes.

In step S11.2, at normal temperature and pressure in air, a PEDOT:PSS aqueous solution was inkjet printed on one side of the anode away from the substrate, and then the hole injection layer was obtained by a constant-temperature thermal treatment at 150 °C for 30 minutes.

In step S11.3, at normal temperature and pressure under a nitrogen atmosphere, a TFB-chlorobenzene solution was inkjet printed on one side of the hole injection layer away from the anode, and then the hole transport layer was obtained by a constant-temperature thermal treatment at 150 °C for 30 minutes.

In step S11.4, at normal temperature and pressure under a nitrogen atmosphere, the light-emitting layer was formed on one side of the hole transport layer away from the hole injection layer. A method for forming the light-emitting layer was carried out with reference to the preparation method for the patterned quantum dot thin film in Example 1.

In step S11.5, at normal temperature and pressure under a nitrogen atmosphere, a nano-ZnO-ethanol solution was inkjet printed on the light-emitting layer away from the hole transport layer, and then the electron functional layer was obtained by a constant-temperature thermal treatment at 80 °C for 30 minutes.

In step S11.6, a prefabricated device including the electron functional layer was placed in an evaporation chamber with an air pressure of 4×10⁻⁶ mbar, then the cathode was formed on one side of the electron functional layer away from the light-emitting layer by evaporating aluminium through a mask plate, and then an ultraviolet curing adhesive was used for encapsulation to obtain the photoelectric device.

### Example 12

The present embodiment provides a photoelectric device and a preparation method thereof. Compared with the photoelectric device in Example 11, an only difference of the photoelectric device in the present embodiment is that the material of the light-emitting layer is replaced with the green quantum dot CdSe/Cd₁₋ₓZnₓSe_{1-y}S_{y}/ZnS having an oleic acid ligand attached to a surface thereof, and the light-emitting layer has a green light-emitting array structure.

Compared with the method for preparing the photoelectric device in Example 11, an only difference of a method for preparing the photoelectric device in the present embodiment was that step S11.4 was replaced with “at normal temperature and pressure under a nitrogen atmosphere, the light-emitting layer was formed on one side of the hole transport layer away from the hole injection layer. A method for forming the light-emitting layer was carried out with reference to the preparation method for the patterned quantum dot thin film in Example 2”.

### Example 13

The present embodiment provides a photoelectric device and a preparation method thereof. Compared with the photoelectric device in Example 11, an only difference of the photoelectric device in the present embodiment is that the material of the light-emitting layer is replaced with the blue quantum dot Cd₁₋ₓZnₓS/ZnS having an oleic acid ligand attached to a surface thereof.

Compared with the method for preparing the photoelectric device in Example 11, an only difference of a method for preparing the photoelectric device in the present embodiment was that step S11.4 was replaced with “at normal temperature and pressure under a nitrogen atmosphere, the light-emitting layer was formed on one side of the hole transport layer away from the hole injection layer. A method for forming the light-emitting layer was carried out with reference to the preparation method for the patterned quantum dot thin film in Example 3”.

### Comparative Example 1

The present comparative example provides a preparation method for a patterned quantum dot thin film. Compared with the preparation method for a patterned quantum dot thin film in Example 1, the preparation method for a patterned quantum dot thin film in the present comparative example was that “triphenylchloromethane” was replaced with “triphenylmethanol”.

In the present comparative example, the red quantum dot thin film after the partial exposure process was soaked in toluene, but no pattern was developed (as shown in FIG. 15). A possible reason is that a photodecomposition rate of triphenylmethanol is slow, thus it is difficult to generate sufficient photosensitive free radicals to undergo a photoreaction with the ligand on the surface of the quantum dot. Therefore, triphenylmethanol may not pattern the quantum dot.

### Comparative Example 2

The present comparative example provides a photoelectric device and a preparation method thereof. Compared with the photoelectric device in Example 11, an only difference of the photoelectric device in the present comparative example is that the light-emitting layer is not patterned.

Compared with the photoelectric device in Example 11, an only difference of the photoelectric device in the present comparative example was that step S11.4 was replaced with “at normal temperature and pressure under a nitrogen atmosphere, a solution of a red quantum dot CdSe/CdS which was the same as that of Example 1 with a concentration of 30 mg/mL and n-octane was inkjet printed on one side of the hole transport layer away from the hole injection layer, and then the light-emitting layer was obtained by a constant-temperature thermal treatment at 80 °C for 10 minutes”.

### Comparative Example 3

The present comparative example provides a photoelectric device and a preparation method thereof. Compared with the photoelectric device in Example 11, an only difference of the photoelectric device in the present embodiment is that the material of the light-emitting layer is replaced with the same green quantum dot CdSe/Cd₁₋ₓZnₓSe_{1-y}S_{y}/ZnS with an oleic acid ligand attached to a surface thereof as that of Example 2, and the light-emitting layer is not patterned.

Compared with the photoelectric device in Example 11, an only difference of the photoelectric device in the present comparative example was that step S11.4 was replaced with “at normal temperature and pressure under a nitrogen atmosphere, a solution of the green quantum dot CdSe/Cd₁₋ₓZnₓSe_{1-y}S_{y}/ZnS with a concentration of 30 mg/mL and n-octane was inkjet printed on one side of the hole transport layer away from the hole injection layer, and then the light-emitting layer was obtained by a constant-temperature thermal treatment at 80 °C for 10 minutes”.

### Comparative Example 4

The present comparative example provides a photoelectric device and a preparation method thereof. Compared with the photoelectric device in Example 11, an only difference of the photoelectric device in the present embodiment is that the material of the light-emitting layer is replaced with the same blue quantum dot Cd₁₋ₓZnₓS/ZnS with an oleic acid ligand attached to a surface thereof as that of Example 3, and the light-emitting layer is not patterned.

Compared with the photoelectric device in Example 11, an only difference of the photoelectric device in the present comparative example was that step S11.4 was replaced with “at normal temperature and pressure under a nitrogen atmosphere, a solution of the blue quantum dot Cd₁₋ₓZnₓS/ZnS with a concentration of 30 mg/mL and n-octane was inkjet printed on one side of the hole transport layer away from the hole injection layer, and then the light-emitting layer was obtained by a constant-temperature thermal treatment at 80 °C for 10 minutes”.

### Test Example

Performances of photoelectric devices in Examples 11 to 13, and Comparative Examples 2 to 4 were tested. A FSTAR FPD optical property measurement device including an efficiency test system built with components such as an Ocean Optics USB2000, a LabView-controlled QE-PRO spectrometer, a Keithley 2400, a high-precision digital source meter Keithley 6485, an optical fiber with an inner diameter of 50 μm, device test probes and fixtures, various related connecting wires and data cards, an efficiency test dark box, and a data acquisition system was configured to test parameters of each photoelectric device, for example, a turn-on voltage, a current, a maximum brightness, an electroluminescence intensity, and a luminescence spectrum, then key parameters such as an external quantum efficiency and power efficiency were calculated. Additionally, a lifetime testing device was configured to test a lifetime of each photoelectric device above. The maximum electroluminescence intensity (Lₘₐₓ, cd/m²), the maximum external quantum efficiency (EQEₘₐₓ, %), and a time required for a brightness to decay from 100% to 95% at 1000 nit (T95@1000 nit, h), and the turn-on voltage (Ut, V) of each photoelectric device were obtained.

A method for testing Lₘₐₓ was that driven by a constant current (2 mA), the maximum electroluminescence intensity of a photoelectric device was obtained within a range of driving voltages from 0 V to 8 V. A method for testing a lifetime was that driven by a constant current (2 mA), a 128-channel QLED lifetime testing system was configured to conduct an electroluminescence lifetime analysis on each photoelectric device, a time (T95, h) required for each photoelectric device to decay from the maximum brightness to 95% thereof was recorded, and a time (T95@1000 nit, h) required for each photoelectric device to decay from 100% to 95% at 1000 nit brightness at 1000 nit through a decay fitting formula.

Test results of photoelectric devices are shown in Table 1 below:

TABLE 1
a list of performance test data of photoelectric devices according
to Examples 11 to 13 and Comparative Examples 2 to 4

| Project | EQEₘₐₓ | Lₘₐₓ | T95@1000 nit | Uₜ |
|---|---|---|---|---|
| Group | (%) | (cd/m²) | (h) | (V) |
| Example 11 | 19.1 | 13649 | 7657 | 1.8 |
| Example 12 | 17.5 | 56918 | 8707 | 2.0 |
| Example 13 | 12.0 | 4294 | 61.3 | 2.6 |
| Comparative | 19.8 | 10239 | 7924 | 1.8 |
| Example 2 | | | | |
| Comparative | 18.5 | 64439 | 8931 | 2.0 |
| Example 3 | | | | |
| Comparative | 14.5 | 5022 | 78.3 | 2.6 |
| Example 4 | | | | |

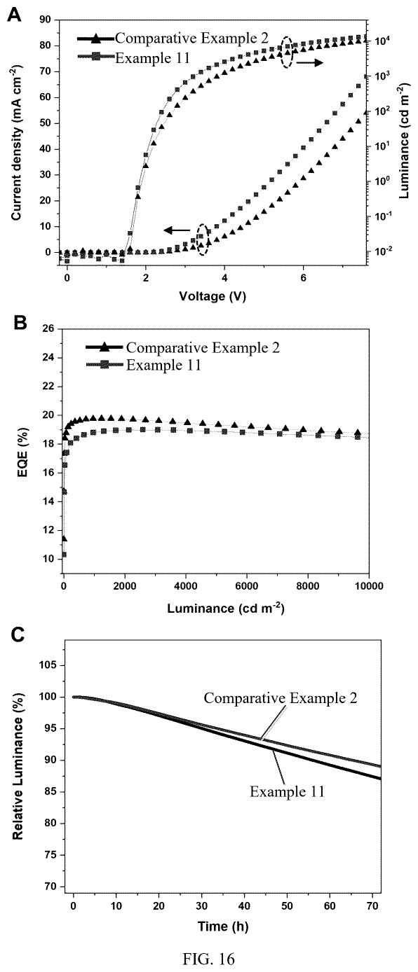

As can be seen from Table 1 and FIG. 16, comprehensive performances of photoelectric devices in Example 11 and Comparative Example 2 are similar. Both them have a turn-on voltage of less than 2 V, Lₘₐₓ reaching 10000 cd/m², EQEₘₐₓ reaching 19%, and T95@1000 nit reaching 7600 h. It is indicated that a method for patterning the light-emitting layer in Example 11 basically does not damage the red quantum dot CdSe/CdS, thus a photoelectric performance of the red quantum dot CdSe/CdS before and after patterning does not change significantly.

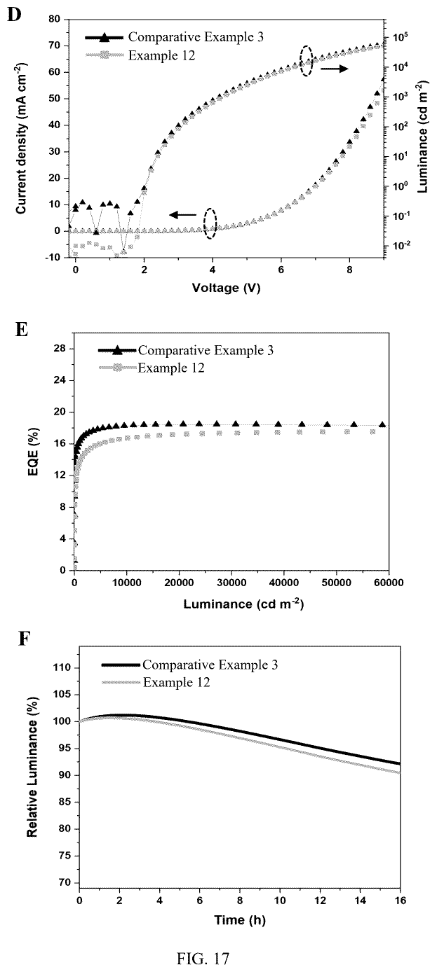

As can be seen from Table 1 and FIG. 17, comprehensive performances of photoelectric devices in Example 12 and Comparative Example 3 are similar. Both of them have a turn-on voltage of 2 V, Lₘₐₓ reaching 56900 cd/m², EQEₘax reaching 17.5%, and T95@1000 nit reaching 8700 h. It is indicated that a method for patterning the light-emitting layer in Example 12 basically does not damage the green quantum dot CdSe/Cd₁₋ₓZnₓSe_{1-y}S_{y}/ZnS, thus a photoelectric performance of the green quantum dot CdSe/Cd₁₋ₓZnₓSe_{1-y}S_{y}/ZnS before and after patterning does not change significantly.

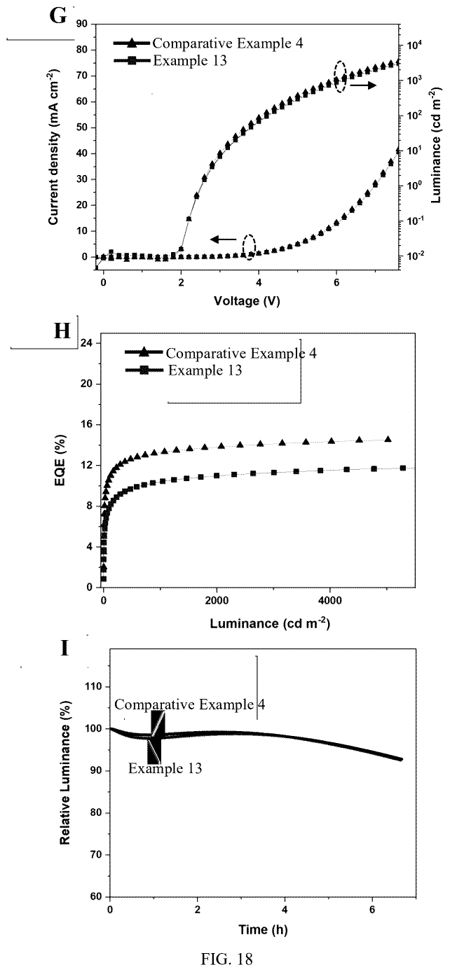

As can be seen from Table 1 and FIG. 18, an overall performance difference between photoelectric devices in Example 13 and Comparative Example 4 is slight. Both of them have a turn-on voltage of 2.6 V, Lₘₐₓ reaching 4200 cd/m², EQEₘₐₓ reaching 12%, and T95@1000 nit reaching 61 h. It is indicated that a method for patterning the light-emitting layer in Example 13 has little damage to the blue quantum dot Cd₁₋ₓZnₓS/ZnS, thus a difference in photoelectric performances of the blue quantum dot Cd₁₋ₓZnₓS/ZnS before and after patterning is small.

The preparation method for a patterned quantum dot thin film, the photoelectric device and the electronic device provided by embodiments of the present disclosure are described in detail above, and specific examples have been applied herein to illustrate principles and implement measures. The foregoing description of embodiments is provided merely to help understand the method and the core idea of the present disclosure. For those skilled in the art, variations will be made in specific implementation and application scope in accordance with the teachings of the present disclosure. In view of the foregoing, the contents of this specification should not be construed as limiting the application.

1. A preparation method for a patterned quantum dot thin film, comprising:
forming a quantum dot film layer comprising a quantum dot and a ligand remover on one side of a substrate provided, wherein a surface of the quantum dot is connected with a ligand;
performing a partial exposure process on the quantum dot film layer such that the quantum dot film layer comprises an exposed part and an unexposed part, wherein the ligand in the exposed part is detached from the quantum dot; and
removing the unexposed part to obtain the patterned quantum dot thin film;
wherein the ligand remover is a compound represented by the following general formula (I): 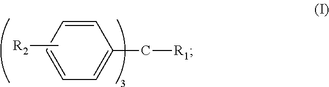
in the general formula (I), R₂ is selected from at least one of a hydrogen atom, a halogen atom, a substituted or unsubstituted alkyl group, a substituted or unsubstituted alkoxy group, a substituted or unsubstituted aryl group, and a substituted or unsubstituted heteroaryl group; and
in the partial exposure process, the ligand remover in the exposure part loses R₁ to form an electrophilic group, so that the ligand in the exposure part binds to the electrophilic group and is detached from the quantum dot.

2. The preparation method according to claim 1, wherein
the R₁ is selected from a group that is detached from the ligand remover in the partial exposure process;
a pKa value of a conjugated acid formed after the R₁ accepts a proton in water at 25 °C ranges between −10 and 9.

3. The preparation method according to claim 2, wherein the R₁ is selected from a halogen atom, a p-toluenesulfonyl group, a p-toluenesulfonyloxy group, a mercapto group, a cyano group, an azide group, a thiocyano group or an alkoxycarbonyl group.

4. The preparation method according to claim 1, wherein the removing the unexposed part comprises performing an elution process on the quantum dot film layer with an eluent dissolving the unexposed part.

5. The preparation method according to claim 4, wherein a dielectric constant of the eluent is less than 10;
the eluent is selected from at least one of toluene, chlorobenzene, n-hexane, n-octane, n-heptane, cyclohexane, dichloromethane, chloroform and tetrahydrofuran.

6. The preparation method according to claim 1, wherein a number of carbon atoms of the substituted or unsubstituted alkyl group ranges from 1 to 10, a number of carbon atoms of the substituted or unsubstituted alkoxy group ranges from 1 to 10, a number of ring atoms of the substituted or unsubstituted aryl group ranges from 6 to 20, or a number of ring atoms of the substituted or unsubstituted heteroaryl group ranges from 5 to 20.

7. The preparation method according to claim 1, wherein an illumination wavelength of the partial exposure process ranges from 200 nm to 500 nm;
an illumination energy of the partial exposure process ranges from 50 mJ/cm² to 6000 mJ/cm²;
a molar absorbance coefficient of the ligand remover at the illumination wavelength of the partial exposure process ranges from 10 cm⁻¹M⁻¹ to 10⁵ cm⁻¹M⁻¹.

8. The preparation method according to claim 1, wherein the ligand remover is selected from at least one of triphenylmethyl chloride, triphenylmethyl bromide, triphenylmethyl iodide, triphenylacetonitrile or triphenylmethyl mercaptan.

9. The preparation method according to claim 1, wherein the ligand is selected from a ligand having a hydrocarbon chain with 6 to 30 carbon atoms.

10. The preparation method according to claim 9, wherein the ligand is selected from at least one of a fatty amine ligand comprising 6 to 20 carbon atoms, a fatty acid ligand comprising 6 to 20 carbon atoms, and a fatty thiol ligands comprising 6 to 20 carbon atoms.

11. The preparation method according to claim 1, wherein a step of forming the quantum dot film layer on the side of the substrate comprises disposing a solution comprising the quantum dot and the ligand remover on the side of the substrate to form the quantum dot film layer.

12. The preparation method according to claim 11, wherein in the solution, a concentration of the quantum dot ranges from 1 mg/mL to 1000 mg/mL.

13. The preparation method according to claim 11, wherein in the solution, a mass ratio of the quantum dot to the ligand remover ranges from 1:0.01 to 1:2.

14. The preparation method according to claim 11, the quantum dot is selected from at least one of a quantum dot with a single component, a quantum dot with a core-shell structure, an inorganic perovskite quantum dot, an organic perovskite quantum dot, or an organic-inorganic hybrid perovskite quantum dot, wherein a material of the quantum dot with the single component, a material of the core of the quantum dot with the core-shell structure, and a material of a shell layer of the quantum dot with the core-shell structure are each independently selected from one or more of a group II-VI compound, a group III-V compound, a group IV-VI compound, or a group I-III-VI compound;
wherein the group II-VI compound is selected from at least one of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe, the group III-V compound is selected from at least one of GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, the group IV-VI compound is selected from at least one of SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, or SnPbSTe, and the group I-III-VI compound is selected from at least one of CuInS₂, CuInSe₂, or AgInS₂.

15. A photoelectric device comprising:
an anode;
a cathode disposed opposite the anode; and
a light-emitting layer disposed between the anode and the cathode;
wherein the light-emitting layer comprises a plurality of quantum dot layers, a material of each of the quantum dot layers comprises a quantum dot with at least one emission color, and a preparation method for at least one quantum dot layer of the quantum dot layers comprises the following steps:
forming a quantum dot film layer comprising a quantum dot and a ligand remover on one side of a substrate provided, wherein a surface of the quantum dot is connected with a ligand;
performing a partial exposure process on the quantum dot film layer such that the quantum dot film layer includes an exposed part and an unexposed part, wherein the ligand in the exposed part is detached from the quantum dot; and
removing the unexposed part to obtain the patterned quantum dot thin film;
wherein the ligand remover is a compound represented by the following general formula (I): 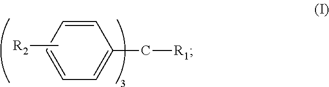
in the general formula (I), R₂ is selected from at least one of a hydrogen atom, a halogen atom, a substituted or unsubstituted alkyl group, a substituted or unsubstituted alkoxy group, a substituted or unsubstituted aryl group, and a substituted or unsubstituted heteroaryl group; and
in the partial exposure process, the ligand remover in the exposure part loses R₁ to form an electrophilic group, so that the ligand in the exposure part binds to the electrophilic group and is detached from the quantum dot.

16. The photoelectric device according to claim 15, wherein the R₁ is selected from a halogen atom, a p-toluenesulfonyl group, a p-toluenesulfonyloxy group, a mercapto group, a cyano group, an azide group, a thiocyano group or an alkoxycarbonyl group;
the removing the unexposed part comprises performing an elution process on the quantum dot film layer with an eluent dissolving the unexposed part;
the ligand remover is selected from at least one of triphenylmethyl chloride, triphenylmethyl bromide, triphenylmethyl iodide, triphenylacetonitrile or triphenylmethyl mercaptan;
the ligand is selected from a ligand having a hydrocarbon chain with 6 to 30 carbon atoms;
an illumination wavelength of the partial exposure process ranges from 200 nm to 500 nm, and/or an illumination energy of the partial exposure process ranges from 50 mJ/cm² to 6000 mJ/cm².

17. The photoelectric device according to claim 15, wherein the photoelectric device further comprises an electron functional layer disposed between the cathode and the light-emitting layer, wherein the electron functional layer comprises an electron transport layer and/or an electron injection layer, and for the electron functional layer comprising the electron transport layer and the electron injection layer, the electron transport layer is closer to the light-emitting layer than the electron injection layer, and the electron injection layer is closer to the cathode than the electron transport layer;
the photoelectric device further comprises a hole functional layer disposed between the light-emitting layer and the anode, wherein the hole functional layer comprises a hole injection layer and/or a hole transport layer, and for the hole functional layer comprising the hole injection layer and the hole transport layer, the hole injection layer is closer to the anode than the hole transport layer, and the hole transport layer is closer to the light-emitting layer than the hole injection layer;
materials of the anode and the cathode are each independently selected from at least one of a metal, a carbon material, or a first metal oxide, wherein the metal is selected from at least one of Al, Ag, Cu, Mo, Au, Ba, Ca or Mg, the carbon material is selected from at least one of graphite, carbon nanotube, graphene or carbon fiber, and the first metal oxide is selected from at least one of indium tin oxide, fluorine-doped tin oxide, antimony tin oxide, aluminium-doped zinc oxide, gallium-doped zinc oxide, indium-doped zinc oxide or magnesium-doped zinc oxide.

18. The photoelectric device according to claim 17, wherein a material of the electron transport layer comprises a second metal oxide selected from at least one of ZnO, TiO₂, SnO₂, BaO, Ta₂O₃, ZrO₂, TiLiO, ZnGaO, ZnAlO, ZnMgO, ZnSnO, ZnLiO, InSnO, AlZnO, ZnOCl, ZnOF, or ZnMgLiO;
a material of the electron injection layer comprises at least one of an alkali metal halide, an alkali metal organic complex, or an organophosphine compound, wherein the organophosphine compound is selected from at least one of an organic phosphorus oxide, an organic thiophosphine compound, or an organic selenophosphine compound;
a material of the hole injection layer is selected from at least one of poly(3,4-ethylenedioxythiophene)-poly(styrenesulfonate), copper(II) phthalocyanine, titanyl phthalocyanine, 4,4′,4″-tris(N-3-methylphenyl-N-phenylamino)triphenylamine, 4,4′,4″-tris[2-naphthyl(phenyl)amino]triphenylamine, hexaazatriphenylenehexacabonitrile, 2,3,5,6-tetrafluoro-7,7,8,8-tetracyanoquinodimethane, a transition metal oxide, or a transition metal chalcogenide, wherein the transition metal oxide is selected from at least one of an oxide of nickel, an oxide of molybdenum, an oxide of tungsten, an oxide of vanadium, an oxide of chromium, or an oxide of copper, and the transition metal chalcogenide is selected from at least one of a sulfide of molybdenum, a selenide of molybdenum, a sulfide of tungsten, a selenide of tungsten, or a sulfide of copper;
a material of the hole transport layer is selected from at least one of poly(9,9-dioctylfluorene-co-N-(4-butylphenyl)diphenylamine), poly(3-hexylthiophene-2,5-diyl), poly(N-vinylcarbazole), poly[N,N′-bis(4-butylphenyl)-N,N′-bis(phenyl)-benzi, poly(N,N′-bis(4-butylphenyl)-N,N′-diphenyl-1,4-benzenediamine-co-9,9-dioctylfluorene, 4,4′,4″-tris(carbazol-9-yl)-triphenylamine, 4,4′-bis(N-carbazolyl)-1,1′-biphenyl, N,N′-bis(3-methylphenyl)-N,N′-bis(phenyl)benzidine, N,N′-bis-(1-naphthalenyl)-N,N′-bis-phenyl-(1,1′-biphenyl)-4,4′-diamine, poly(3,4-ethylenedioxythiophene)-poly(styrenesulfonate), doped or undoped graphene, C60, NiO, MoO₃, WO₃, V₂O₅, CrO₃, CuO, or P-type gallium nitride.

19. An electronic device comprising a photoelectric device, wherein the photoelectric device comprises:
an anode;
a cathode disposed opposite the anode; and
a light-emitting layer disposed between the anode and the cathode;
wherein the light-emitting layer comprises a plurality of quantum dot layers, a material of each of the quantum dot layers comprises a quantum dot with at least one emission color, and a preparation method for at least one quantum dot layer of the quantum dot layers comprises the following steps:
forming a quantum dot film layer comprising a quantum dot and a ligand remover on one side of a substrate provided, wherein a surface of the quantum dot is connected with a ligand;
performing a partial exposure process on the quantum dot film layer such that the quantum dot film layer includes an exposed part and an unexposed part, wherein the ligand in the exposed part is detached from the quantum dot; and
removing the unexposed part to obtain the patterned quantum dot thin film;
wherein the ligand remover is a compound represented by the following general formula (I): 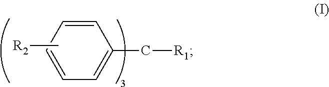
in the general formula (I), R₂ is selected from at least one of a hydrogen atom, a halogen atom, a substituted or unsubstituted alkyl group, a substituted or unsubstituted alkoxy group, a substituted or unsubstituted aryl group, and a substituted or unsubstituted heteroaryl group; and
in the partial exposure process, the ligand remover in the exposure part loses R₁ to form an electrophilic group, so that the ligand in the exposure part binds to the electrophilic group and is detached from the quantum dot.

20. The electronic device according to claim 19, wherein the R₁ is selected from a halogen atom, a p-toluenesulfonyl group, a p-toluenesulfonyloxy group, a mercapto group, a cyano group, an azide group, a thiocyano group or an alkoxycarbonyl group;
the removing the unexposed part comprises performing an elution process on the quantum dot film layer with an eluent dissolving the unexposed part;
the ligand remover is selected from at least one of triphenylmethyl chloride, triphenylmethyl bromide, triphenylmethyl iodide, triphenylacetonitrile or triphenylmethyl mercaptan;
the ligand is selected from a ligand having a hydrocarbon chain with 6 to 30 carbon atoms;
an illumination wavelength of the partial exposure process ranges from 200 nm to 500 nm, and/or an illumination energy of the partial exposure process ranges from 50 mJ/cm² to 6000 mJ/cm².
